(19) United States
(12) Patent Application Publication
(10) Pub. No.: US 2025/0216790 A1
(43) Pub. Date: Jul. 3, 2025

(54) MATERIALS AND METHODS FOR FORMING PATTERNED MASK ON SUBSTRATE

(71) Applicant: Tokyo Electon Limited, Tokyo (JP)

(72) Inventors: Phillip D. Hustad, Longmont, CO (US); Jordan B. Greenough, Schenectady, NY (US); Max J. Klemes, Schenectady, NY (US)

(21) Appl. No.: 18/990,253

(22) Filed: Dec. 20, 2024

Related U.S. Application Data
(60) Provisional application No. 63/616,086, filed on Dec. 29, 2023.

(51) Int. Cl. G03F 7/26; G03F 7/30; H01L 21/027

(52) U.S. Cl. CPC G03F 7/265; G03F 7/30; H01L 21/0274

(57) ABSTRACT

A method includes depositing an overcoat in openings of a relief pattern supported by a substrate. The relief pattern includes a solubility-shifting agent. The overcoat and the relief pattern have different solubility-shifting mechanisms. The method further includes generating a catalyst by activating the solubility-shifting agent and diffusing the catalyst a predetermined distance from structures of the relief pattern into the overcoat to form soluble regions in the overcoat. The soluble regions is soluble in a predetermined developer while the relief pattern remains insoluble in the predetermined developer. The method further includes developing the substrate with the predetermined developer to remove the soluble regions of the overcoat.

### CROSS-REFERENCE TO RELATED APPLICATIONS

This application claims the benefit of U.S. Provisional Application No. 63/616,086, filed on Dec. 29, 2023, which application is hereby incorporated herein by reference.

### TECHNICAL FIELD

The present disclosure relates generally to methods for processing a substrate, and, in particular embodiments, to photolithography materials and processes in methods for forming a patterned mask on a substrate during manufacturing of semiconductor devices.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning of nanoscale features.

### SUMMARY

In accordance with an embodiment of the present disclosure, a method includes depositing an overcoat in openings of a relief pattern supported by a substrate. The relief pattern includes a solubility-shifting agent. The overcoat and the relief pattern have different solubility-shifting mechanisms. The method further includes generating a catalyst by activating the solubility-shifting agent and diffusing the catalyst a predetermined distance from structures of the relief pattern into the overcoat to form soluble regions in the overcoat. The soluble regions is soluble in a predetermined developer while the relief pattern remains insoluble in the predetermined developer. The method further includes developing the substrate with the predetermined developer to remove the soluble regions of the overcoat.

In accordance with another embodiment of the present disclosure, a method includes providing a substrate with a relief pattern thereon. The relief pattern includes a solubility-shifting agent. The relief pattern includes a first material including acid-labile groups. The method further includes depositing an overcoat over the relief pattern. The overcoat includes a second material including curable groups and cleavable groups. The method further includes generating a catalyst from the solubility-shifting agent, diffusing the catalyst from the relief pattern into the overcoat to form deprotected regions in the overcoat, and selectively removing the deprotected regions of the overcoat.

In accordance with yet another embodiment of the present disclosure, a method includes forming a relief pattern on a substrate from a layer of photoresist by exposing the photoresist to actinic radiation to activate a photoacid generator. The photoresist includes the photoacid generator and a solubility-shifting agent. The method further includes depositing an overcoat in openings of the relief pattern. The overcoat includes a degradable thermoset. The method further includes curing the overcoat, generating a catalyst from the solubility-shifting agent, diffusing the catalyst from the relief pattern into the overcoat to form deprotected regions in the overcoat, and selectively removing the deprotected regions of the overcoat.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1E illustrate an example process flow for forming a patterned mask over a substrate that avoids additional dissolution-inhibiting steps by activating a solubility-shifting agent to at least reach a solubility threshold of an overcoat without reaching a solubility threshold of a relief pattern in accordance with various embodiments;

FIGS. 2A-2D illustrate an example process flow for forming a patterned mask over a substrate where a solubility-shifting agent is utilized as a thermal acid generator when solubilizing an overcoat material in accordance with various embodiments;

FIGS. 3A-3C illustrate an example process flow for forming a patterned mask over a substrate where a solubility shifting agent is utilized as a photoacid generator when forming a relief pattern and as a thermal acid generator when solubilizing an overcoat material in accordance with various embodiments;

FIG. 4 illustrates a flow diagram of a method for forming a patterned mask over a substrate in accordance with various embodiments;

FIG. 5 illustrates a flow diagram of a method for forming a patterned mask over a substrate in accordance with various embodiments; and

FIG. 6 illustrates a flow diagram of a method for forming a patterned mask over a substrate in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Embodiments of the present disclosure relate to materials and methods for forming patterned masks on substrates using photolithography processes with improved control over pattern formation. In various embodiments, a relief pattern containing a solubility-shifting agent is formed on a substrate, and an overcoat material is deposited in openings of the relief pattern. The relief pattern and overcoat have different solubility-shifting mechanisms and solubility thresholds relative to a developer.

The solubility-shifting agent in the relief pattern is activated to generate a catalyst that diffuses a predetermined distance into the overcoat material to form soluble regions that are soluble in a predetermined developer, while the relief pattern remains insoluble in the predetermined developer. In some embodiments, the catalyst level is controlled to reach the solubility threshold of the overcoat in the predetermined developer without reaching the solubility threshold of the relief pattern in the predetermined developer. In other embodiments, the catalyst shift in the solubility of the relief patterned. However, the relief patterned remains insoluble in the predetermined developer. The soluble regions of the overcoat are then selectively removed using a developer to create a patterned mask structure. This approach enables improved control over pattern dimensions without requiring additional dissolution-inhibiting steps.

Various embodiments of the present disclosure offer several advantages. Various embodiments provide improved control over pattern formation while avoiding additional dissolution-inhibiting steps that would otherwise be needed to prevent dissolution of the relief pattern structures. The selective solubility-shifting mechanism enables improved control over pattern dimensions by tuning the catalyst diffusion depth through variables like acid molecular weight, acid concentration, bake temperature/time, and polymer composition. The methods can utilize different types of solubility-shifting agents including acids, thermal acid generators, photoacid generators, or combinations thereof to achieve the desired patterning control.

Further advantage is the flexibility in material selection and processing conditions. The relief pattern and overcoat materials can be chosen to have different solubility-shifting mechanisms and thresholds, allowing for selective removal of overcoat regions while preserving the relief pattern structures. The overcoat material can include various compositions like degradable thermosets with curable and cleavable groups that provide additional control over the patterning process. The methods are compatible with either positive tone development using aqueous developers or negative tone development using organic solvent-based developers.

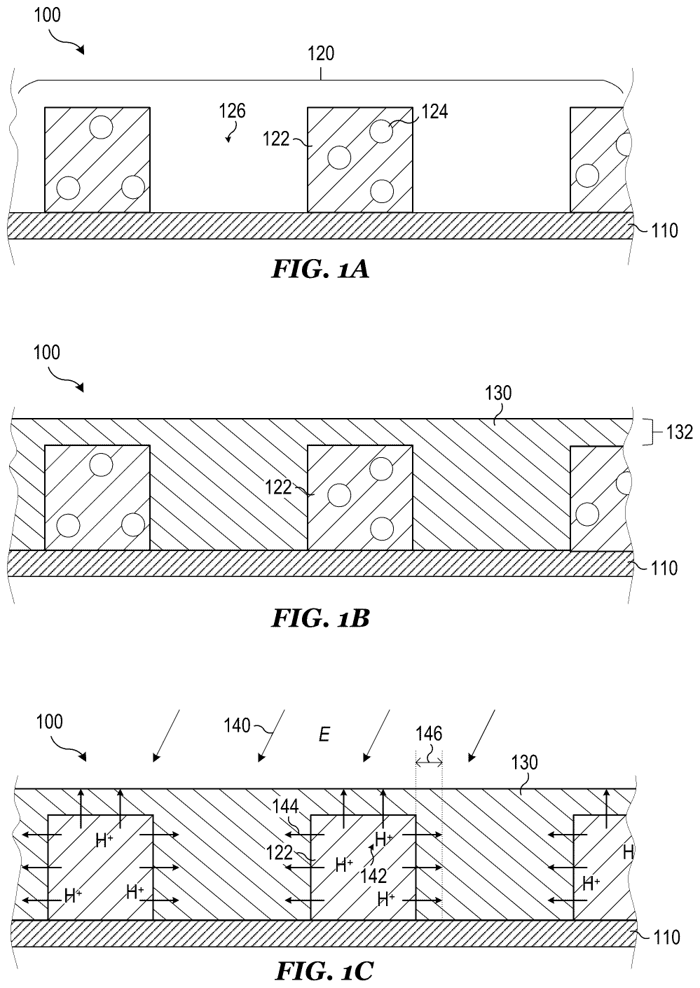

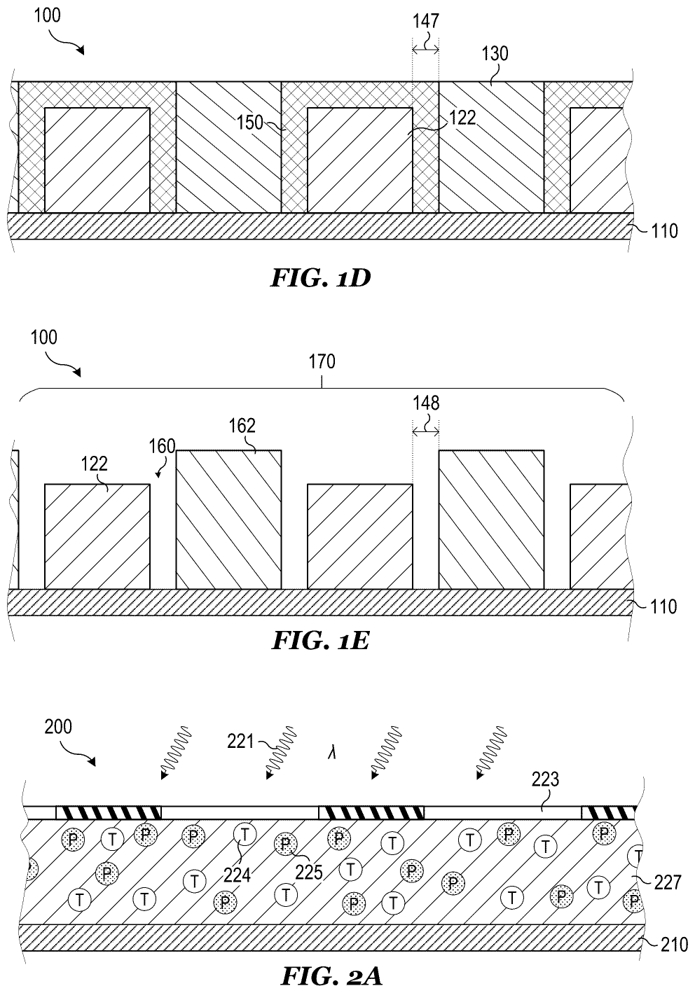

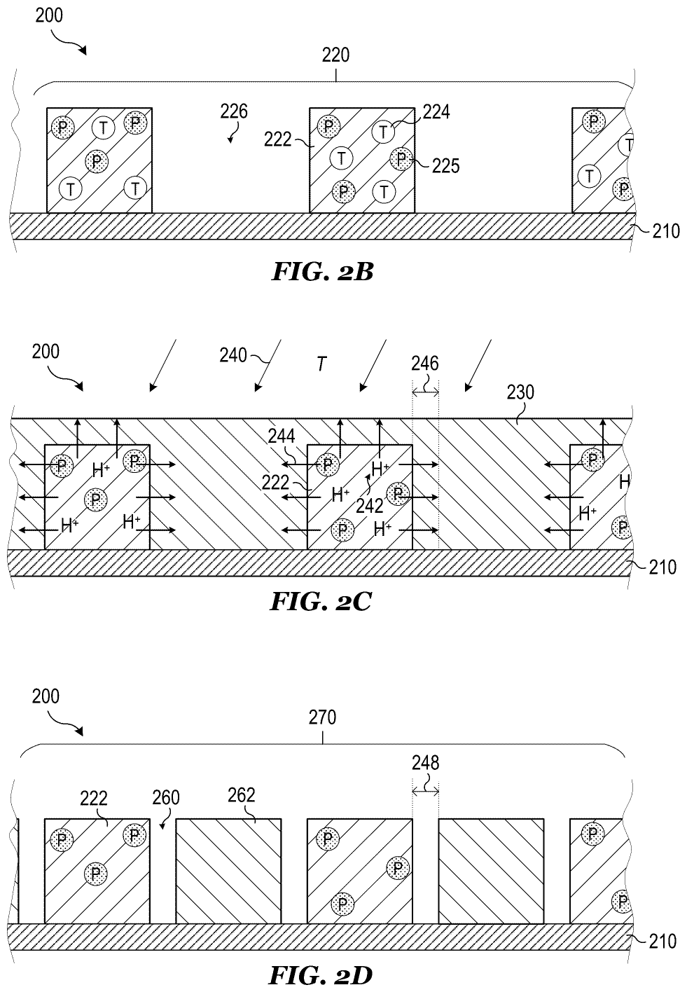

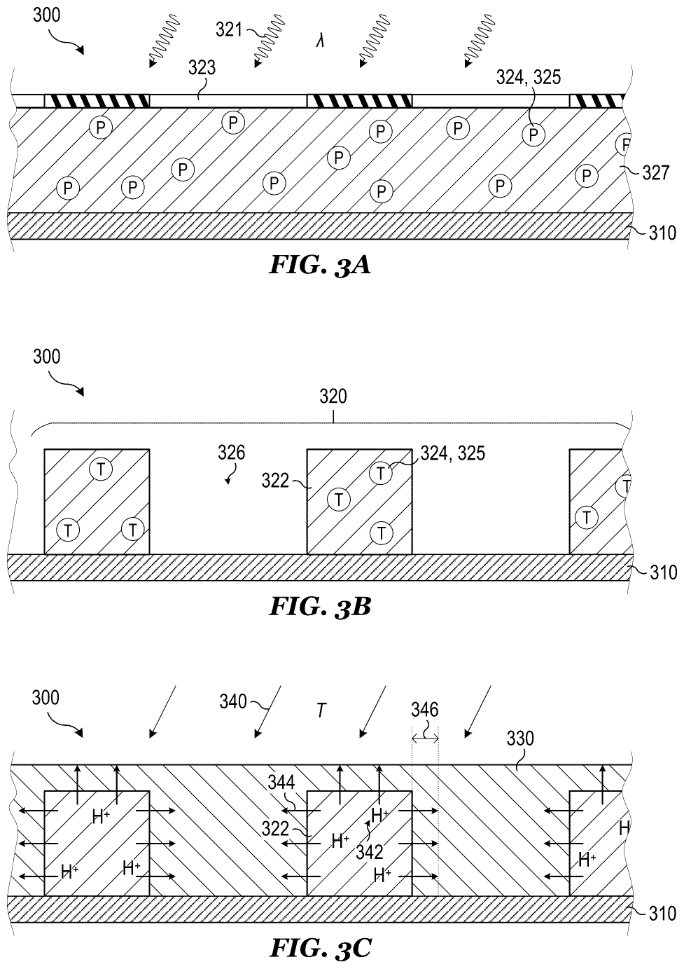

Embodiments provided below describe various methods of processing a substrate, and, in particular embodiments, photolithography materials and processes in methods for forming a patterned mask on a substrate without additional dissolution-inhibiting steps. Some example embodiments of the present disclosure are described in detail with reference to FIGS. 1A-1E, 2A-2D, and 3A-3C. FIGS. 1A-1E are used to describe an embodiment process flow for forming a patterned mask on a substrate. FIGS. 2A-2D are used to describe another embodiment process flow for forming a patterned mask on a substrate. FIGS. 3A-3C are used to describe yet another embodiment process flow for forming a patterned mask on a substrate.

It should be noted that here and in the following a convention has been adopted for brevity and clarity wherein elements of FIGS. 1A-1E referred to by numerical references 1xx are similar to elements of FIGS. 2A-2D referred to by numerical references 2xx and elements of FIGS. 3A-2C referred to by numerical references 3xx. Accordingly, descriptions of the elements 2xx and 3xx will not be repeated.

FIGS. 1A-1E illustrates an example process flow for forming a patterned mask on a substrate that avoids additional dissolution-inhibiting steps by activating a solubility-shifting agent to at least reach a solubility threshold of an overcoat without reaching a solubility threshold of a relief pattern in accordance with an embodiment of the present disclosure.

Referring to FIG. 2A, a process flow 100 begins with a relief pattern 120 on a substrate 110. The relief pattern 120 may be formed on the substrate 110 as part of the process flow 100 or be formed as part of a separate process and used as a starting point for the process flow 100. For example, the example process flow 100 may include forming the relief pattern 120 using a lithographic or other suitable patterning process (e.g., from a layer of photoresist using a photolithographic process).

The relief pattern 120 includes structures 122 on the substrate 110 separated by openings 126. The structures 122 and openings 126 of the relief pattern 120 may be arranged in any desired pattern such as a uniform pattern of mandrels or an irregular pattern including various shapes, dimensions, and spacing. In some embodiments, a first material of the relief pattern 120 may comprises one or more polymers having acid-labile groups. The first material of the relief pattern 120 includes a solubility-shifting agent (SSA) 124. The SSA 124 in the structures 122 has not been activated at this stage of the process flow 100. Consequently, the structures 122 are insoluble relative to a predetermined developer. The predetermined developer may be any suitable developer. In various embodiments, the predetermined developer is an aqueous developer and comprises tetramethylammonium hydroxide (TMAH) in some embodiments.

In the present disclosure, for an embodiment, the term “substrate” (e.g., substrate 110) can be used generally and as a shorthand description for an underlying structure that can include any combination of layers, materials, structures, devices, and a wafer of any suitable structure. For example, the substrate 110 of an embodiment can include one or more bottom anti-reflective coating (BARC) layers, one or more developable BARC (dBARC) layers, one or more etch stop layers, one or more hard mask layers, one or more dielectric layers, one or more intermetal dielectric layers, one or more conductive lines/layers/interconnects, one or more transistor structures, one or more capacitor structures, one or more resistor structures, one or more inductor structures, one or more memory cells, or any combination thereof.

In some embodiments, the SSA 124 can be formed in situ during the deposition of the first material of the relief pattern 120. In such embodiments, the SSA 124 can be evenly distributed throughout the first material, for example, but not necessarily. In some embodiments, the first material can be deposited without the SSA 124 and the SSA 124 can be put into the first material thereafter. For example, in some embodiments, the SSA 124 can be implanted or diffused into the first material. The first material of the of the relief pattern 120 can be soluble in a first developer containing an organic solvent and insoluble in a second developer containing a quaternary ammonium hydroxide in an aqueous solution (e.g., TMAH).

In some embodiments, the SSA 124 may include an agent-generating ingredient that, in response to a suitable agent-activation trigger (e.g., heat and/or radiation), generates a solubility-changing chemical or a catalyst (e.g., an acid). Example agent-generating ingredients can include a thermal-acid generator (TAG) that is configured to generate an acid in response to heat or a photo-acid generator (PAG) that is configured to generate an acid in response to actinic radiation.

While describing the example embodiments of the present disclosure, the term “solubility shifting agent” or “SSA” can refer to a substance in a general sense that if not already a catalyst agent (e.g., acid) itself, it can generate and/or can transform (e.g., by heat and/or certain radiation of light) to a catalyst agent and/or constituent parts that includes a catalyst agent that can be used in a chemical reaction to shift or change a solubility property of a material.

In some embodiments, the SSA 124 includes acids, photoacid generators, and thermal acid generators, where the pKₐ of the acid is greater than zero and less than 4. In an embodiments, the SSA 124 does not include camphorsulfonic acid. In other embodiments, the SSA 124 includes alkyl sulfonic acids, sulfamic acids, phosphonic acids, or the like. Alkylsulfamic acids have the pKₐ ranging from 1 to 3. Phosphonic acids possess two acidic protons, with a first pKₐ ranging from 1.1 to 2.3 and the a second pKₐ ranging from 5.3 to 7.2. Additional exemplary compositions for the SSA 124 are described below in greater detail.

In some embodiments when the SSA 124 comprises a PAG, after forming the first material (e.g., photoresist) of the relief pattern 120, a reticle (not shown) may be placed over the first material. The reticle may be used to modulate a dose (or an intensity) of a radiation (e.g., actinic radiation) that is used to expose the first material. In such embodiments, the reticle may comprise regions of different transparency to the radiation (e.g., opaque and transparent regions). The first material is then subject to an exposure step through the reticle. The radiation exposes exposed regions of the first material while unexposed (or unmodified) regions of the first material are protected by the reticle. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology.

In some embodiments, the radiation generates a catalyst (e.g., an acid) in the exposed regions of the first material. The catalyst can be generated from the SSA 124 (e.g., PAG) that is present in the first material under the influence of the radiation and chemically transforms exposed portions of the first material to converted region of a second material using the catalyst as a chemical reaction catalyst, such that the second material is soluble in a suitable developer. In an embodiment, the suitable developer comprises a quaternary ammonium hydroxide in an aqueous solution (e.g., TMAH). Subsequently, the exposed regions of the first material may be removed by performing a developing process using a positive-tone developer (e.g., TMAH). The developing process forms the openings 126 in the first material that expose portions of the substrate 110. The unexposed regions of the first material form the plurality of structures 122 (e.g., mandrels). In other embodiments, the unexposed regions of the first material may be removed by performing a developing process using a negative-tone developer (e.g., organic developer). In such embodiments, the exposed regions of the first material form the plurality of structures (e.g., mandrels). In an embodiment, the organic developer may comprise n-butyl acetate (NBA), 2-heptanone, a combination thereof, or the like.

In the present disclosure, the terms “soluble” and “insoluble” are used in a relative sense, not in an absolute sense. That is, the term “insoluble” as used herein refers to one subject material being dissolved or removed much faster and much more effectively compared to another adjacent non-subject material, such as an order of magnitude or more faster and more effectively, and not to necessarily be that the other adjacent non-subject material experiences no dissolving or removal, but rather that the subject material is removed so much faster and more effectively that the subject material can be dissolved and removed sufficiently or to its full extent while only a small amount or even only a negligible amount of the other adjacent non-subject material is dissolved and removed, such that most of or almost all of the other adjacent non-subject material at the stopping point of the dissolving and removing of the subject material, as can be apparent to one of ordinary skill in the art pertaining to the present disclosure.

Referring to FIG. 1B, an overcoat 130 is deposited on the substrate 110 to at least partially fill the openings 126 (see FIG. 1) between the structures 122. The overcoat 130 is cast in a solvent that will not intermix with the underlying first material of the structures 122 or will intermix to a degree that will not negatively affect the targeted critical dimension (e.g., final mandrel width, profile, and volume). In some embodiments, a second material for the overcoat 130 is chosen such that the overcoat 130 has a different solubility-shifting mechanism compared to the first material of the relief pattern 120 (see FIG. 1). In some embodiments, the second material may comprise a material that is soluble in organic solvents to enable film coating, crosslinks or cures or otherwise becomes insoluble to the organic solvent after coating, and de-crosslinks or otherwise becomes soluble again when treated with a catalyst portion of/from an SSA (e.g., SSA 124). In some embodiments, the second material may comprise a curable group and a cleavable group. In an embodiment, the second material may comprise a degradable thermoset. In some embodiments, the degradable thermosets may include polyacrylate phthalates, polystyrene phthalates, polystyrene alcohols, polymethacrylate alcohols, polyacrylate alcohols, polymethacrylate acrylates, polyacrylate acrylates, combinations thereof, or the like.

In some embodiments, the second material of the overcoat 130 comprises no chromophore. In some embodiments, the second material of the overcoat 130 comprises low levels of a chromophore with concentration ranging from about 0.1% to about 5% by weight. In an embodiment, the second material of the overcoat 130 comprises a compound (comprising an acid group, alcohol group, or a phenolic group) selected from the group consisting of polymers, oligomers, molecules, and mixtures thereof; and a vinyl ether crosslinker. The polymer or oligomer can be a polymer made from monomers including acrylates, methacrylates, norbornene, vinyl aromatic monomers such as styrene and p-hydroxystyrene, combinations thereof, or the like. Additional exemplary compositions for the overcoat 130 are described below in greater detail.

The overcoat 130 can be deposited using any suitable process, such as spin-on coating/deposition, for example. The overcoat 130 can have an overburden 132 deposited higher than a highest feature of the structures 122, which can be a normal occurrence when using a spin-on coating process for deposition, for example. In some embodiments, there may be no overburden 132 or very minimal (insubstantial) thickness of overburden 132. The process for depositing the overcoat 130 will not be described in detail here because there can be many different processes that can be used to create the overcoat 130, as can be apparent to one of ordinary skill in the art when implementing an embodiment of the present disclosure.

In some embodiments, after depositing the second material of the overcoat 130, a curing process is performed on the second material to cross-link monomers of the second material. The cross-linking alters solubility of the overcoat 130 such that the overcoat 130 becomes insoluble in organic solvents, for example. In an embodiment, the curing process can be a thermal process that is performed by heating the substrate 110 in a process chamber to a temperature between 60° C. and 140° C., in vacuum or under a gas flow. In a particular example, the substrate 110 can be baked for a duration in a range from 0.5 to 5 minutes. In another embodiment, the curing process comprises an ultraviolet (UV) light curing process.

Now referring to FIG. 1C, the SSA 124 is activated by applying activation energy E to the relief pattern 120 (comprising the structures 122) to generate a catalyst 142 (e.g., acid) which diffuses 144 a predetermined distance 146 from the structures 122 into the overcoat 130. The predetermined distance 146 (i.e., the diffusion depth) may be controlled by any combination of diffusion variables to achieve a desired depth of diffusion which is related to the thickness of the solubilized overcoat 130. For example, possible variables that can be modified include, but are not limited to, acid molecular weight, acid concentration, bake temperature, bake time, and polymer composition.

In FIG. 1C, for simplification of the drawings, “H+” can be used as shorthand notation to denote and represent the catalyst 142, which in some embodiments can be an acid, that is being diffused, such as an acid that donates a proton (e.g., H+) in a chemical reaction (e.g., as a catalyst). However, an acid being diffused in an embodiment of the present disclosure is not necessarily limited to one that provides a hydrogen ion. For example, “H+” may not necessarily accurately describe some acid species that can be used in an embodiment of the present disclosure, as can be apparent to one of ordinary skill in the art for which the present disclosure pertains. Thus, the use of “H+” is as a reference in the drawings for the catalyst is not intended to necessarily limit the chemical makeup or chemical action of the catalyst in an embodiment.

The desired CD can be tuned through molecular weight modification of the reactive species generated from the SSA 124, molecular structure of the reactive species, as well as the bake temperature and bake time. Additionally, the CD can be controlled by the composition of the overcoat 130 the reactive species is diffusing into.

The activation energy E may take any suitable form. For example, the activation energy E may be supplied in the form of actinic radiation, thermal energy, or a combination of the two. Light (e.g. electromagnetic radiation) and heat (e.g. convective, conductive, or radiative thermal energy) generate acid from PAGs or TAGs respectively. If a PAG is to be activated, some regions or the entire substrate 110 (including all supported layers) may be irradiated at a corresponding wavelength that activates the PAG. A TAG may be activated by baking the substrate 110 to a temperature sufficient to decompose the TAG. However, the specific mechanism for activating the SSA 124 (see FIG. 1A) depends on the selected SSA and may also include other mechanisms. The activation and diffusion may be performed sequentially or simultaneously. In an embodiment when the SSA 124 (see FIG. 1A) comprises a free acid, the activation process is omitted.

Referring to FIG. 1D, the result of the activation and diffusion of the catalyst 142 (see FIG. 1C) of the SSA 124 are soluble regions 150 adjacent to the structures 122 of the relief pattern 120 (see FIG. 1) which remain insoluble relative to the predetermined developer. In some embodiment, a composition and concentration of the catalyst 142 (e.g., acid) is tuned such that the catalyst 142 (e.g., acid) does not alter solubility of the structures 122 of the relief pattern 120 (see FIG. 1). The soluble regions 150 comprises a converted second material. The converted second material comprises the second material of the overcoat 130 that is chemically transformed using the catalyst 142 (e.g., acid) as a chemical reaction catalyst. In some embodiments, the catalyst 142 (e.g., acid) cleaves cleavable bonds of cleavable groups of the second material of the overcoat 130 and alters solubility of the converted second material. The soluble regions 150 may be also referred to as deprotected regions or solubility-shifted regions. In other embodiments, the catalyst 142 (e.g., acid) can also shift the solubility of the structures 122 of the relief pattern 120 (see FIG. 1).

The soluble regions 150 have a predetermined width 147 that is proportional to the predetermined distance 146. Since, the diffusion into the overcoat 130 causes the solubility shift, the predetermined width 147 of the soluble regions 150 may be equal to the predetermined distance 146 (as illustrated). However, in some cases the catalyst 142 (e.g. acid) may diffuse into regions of the overcoat 130 (farthest from the structures 122) without reaching the solubility threshold of the overcoat 130. Therefore, the predetermined width 147 of the soluble regions 250 is less than or equal to the predetermined distance 146 in practice.

Referring now to FIG. 1E, the substrate 110 supporting the relief pattern 120 (including structures 122) and the overcoat 130 with the soluble regions 150 (see FIG. 1D) is developed using the predetermined developer to form antispacer features 160. Specifically, the result of the development process is the antispacer features 160 defined by the structures 122 of the original relief pattern 120 (see FIG. 1A) and remaining overcoat structures 162 that were not solubilized during the activation and diffusion of the catalyst 142 (see FIG. 1C) of the SSA 124 (see FIG. 1A). The antispacer features 160 may have an antispacer width 148 that is advantageously substantially equal to the predetermined width 147 (see FIG. 1D). The structures 122 of the original relief pattern 120 (see FIG. 1A) and the remaining overcoat structures 162 form a patterned mask 170 on the substrate 110.

In other embodiments when the catalyst 142 (e.g., acid) shifts the solubility of the structures 122 of the relief pattern 120 (see FIG. 1) and the soluble regions 150 (see FIG. 1D) are selectively removed using a predetermined developer (e.g., a negative-tone organic developer). In such embodiments, the solubility-shifted relief pattern 120 (see FIG. 1) remains insoluble in the predetermined developer (e.g., a negative-tone organic developer).

Notably and advantageously, after the activation and diffusion, no additional steps are required to prevent the structures 122 from dissolving in during development with the predetermined developer. Particularly, with the relief pattern material, the overcoat material, and the SSA already selected to prevent a solubility-shift in this scheme, the soluble regions 150 of the overcoat 130 can be removed without removing the structures 122.

The type of materials selected for the structures 122 of the relief pattern 120 (e.g., photoresist), the overcoat 130 (e.g., a resin), and the SSA 124 (e.g., free acid, PAG, TAG, etc.) may affect the process flow 100. For example, selections can be made which can maximize the selectivity between the deprotection rates of the relief pattern material compared to the overcoat material.

The activation energy of a deprotectable monomer within the structures 122 of the relief pattern 120 (see FIG. 1A) may be high relative to the overcoat 130 (see FIG. 1B) to allow for higher deprotection kinetics within the overcoat 130 relative to the structures 122. In some embodiments, the relief pattern 120 comprises a high activation energy group such as methyl adamantyl methacrylate (MAMA), isoadamantyl methacrylate (IAM), or tert-Butyl acrylate (TBA).

Remaining monomers in the relief pattern 120 may be used for line formation and etch pattern transfer specifications. Conventional monomers used in standard lithographic patterning can be selected for this purpose. In some embodiments, the overcoat 130 is transparent over a range of wavelengths (e.g. so that actinic radiation within the range can pass through the overcoat). However, this is not a requirement of the overcoat 130. Additional exemplary compositions for the relief pattern 120 are described below in greater detail.

In some embodiments, a pattern defined by the patterned mask 170 can be transferred to the substrate 110. In an embodiment, the pattern transfer may be accomplished through an etching process while using the patterned mask 170 as an etch mask. In some embodiments, the etching process may be a dry etching technique such as reactive ion etching (RIE), plasma etching, or ion beam etching. In other embodiments, wet etching techniques may be employed. In some embodiments, the pattern transfer process may be followed by the removal of any remaining patterned mask 170. The removal can be accomplished using suitable solvents, plasma ashing techniques, or the like.

Many example materials for the relief pattern 120 (including the SSA 124) and the overcoat 130, relating to the example embodiments of FIGS. 1A-1E, will be described below in the present disclosure.

FIGS. 2A-2D illustrate an example process flow for forming a patterned mask on a substrate where an SSA is utilized as a TAG when solubilizing an overcoat material in accordance with an embodiment of the present disclosure. The process flow of FIGS. 2A-2D may be a specific implementation of other process flows or various stages of other process flows described herein such as the process flow of FIGS. 1A-1E, for example. It should be noted that here and in the following a convention has been adopted for brevity and clarity wherein elements of FIGS. 2A-2D referred to by numerical references 2xx are similar elements of FIGS. 1A-1E referred to by numerical references 1xx, and descriptions of the elements 2xx will not be repeated.

Referring to FIGS. 2A-2D, a process flow 200 optionally includes forming a relief pattern 220 on a substrate 210. In an embodiment, the relief pattern 220 includes a PAG 225 and a TAG 224 as SAAs. To form the relief pattern 220, a layer of photoresist 227 supported by the substrate 210 is exposed to actinic radiation 221. The exposure activates the PAG 225 in the layer of photoresist 227. The PAG 225 is sensitive to a wavelength λ that is included in the spectrum of the actinic radiation 221. The layer of photoresist 227 is exposed to the actinic radiation 221 through a photomask 223 (or obscured by opaque structures formed on the layer of photoresist 227) to form a latent pattern in the layer of photoresist 227. A relief pattern 220 (see FIG. 2B) including structures 222 separated by openings 226 is formed by developing the substrate 210 to remove the latent pattern.

Alternatively, the process flow 200 may begin with the relief pattern 220 already formed as illustrated in FIG. 2B. The structures 222 include both the TAG 224 which was not activated by the actinic radiation 221 and the PAG 225 which was shielded from the actinic radiation 221 by the photomask 223. As a result, the structures 222 of the relief pattern 220 are insoluble relative to a predetermined developer at this stage of the process flow 200.

As illustrated in FIG. 2C, the TAG 224 (see FIG. 2B) is activated to generate a catalyst 242 (e.g., acid) that is diffused 244 a predetermined distance 246 by applying heat 240 having a predetermined temperature T to the substrate 210 including an overcoat 230 formed over the relief pattern 220 (see FIG. 2B). Notably, the PAG 225 is still present in the structures 222, but is not activated by the applied heat 240. The diffusion process may also be promoted partially or entirely using a separate application of heat (e.g. a bake that uses different parameters, such as duration and/or temperature than heat 240 applied to activate the TAG 224).

As illustrated in FIG. 2D, antispacer features 260 with antispacer width 248 are then formed by developing the substrate 210 supporting the relief pattern 220 (including structures 222) and the overcoat 230 using the predetermined developer. Specifically, the result of the development process is antispacer features 260 defined by the structures 222 of the original relief pattern 220 (see FIG. 2A) and remaining overcoat structures 262 that were not solubilized during the activation and diffusion of the TAG 224. The structures 222 of the original relief pattern 220 (see FIG. 2A) and the remaining overcoat structures 262 form a patterned mask 270 on the substrate 210. The PAG 225 was not activated during the application of heat 240 and the activated TAG 224 is insufficient to solubilize the photoresist of the structures 222, but sufficient to solubilize regions of the overcoat 230 to which an appropriate amount of catalyst 242 (e.g., acid) is diffused. For example, the solubility threshold of the photoresist of the relief pattern 220 may be sufficiently higher than the solubility threshold of the overcoat 230. Additionally or alternatively, the catalyst 242 (e.g., acid) may be weak such that it is not capable of significant deprotection of the photoresist of relief pattern 220 (including the structures 222).

In other embodiments, the catalyst 242 (e.g., acid) can also shift the solubility of the structures 222 of the relief pattern 220 (see FIG. 2B). In such embodiments, the solubility-shifted relief pattern 220 (see FIG. 2B) remains insoluble in a predetermined developer (e.g., a negative-tone organic developer) and the soluble regions of the overcoat 230 may be selectively removed using a predetermined developer (e.g., a negative-tone organic developer) to form the antispacer features 260.

The use of the TAG 224 as a secondary source of acid may advantageously be significant variable for tuning selectivity because the strength of the acid generated may be selected to allow for reaction with the overcoat 230 while minimally reacting with the photoresist of the relief pattern 220 at a given process temperature T.

Many example materials for the relief pattern 220 (including the TAG 224 and the PAG 225) and the overcoat 230, relating to the example embodiments of FIGS. 2A-2D, will be described below in the present disclosure.

FIGS. 3A-3C illustrate an example process flow for forming a patterned mask on a substrate where an SSA is utilized as a PAG when forming a relief pattern and as a TAG when solubilizing an overcoat material in accordance with an embodiment of the present disclosure. The process flow of FIGS. 3A-3C may be a specific implementation of other process flows or various stages of other process flows described herein such as the process flow of FIGS. 1A-1E, for example. It should be noted that here and in the following a convention has been adopted for brevity and clarity wherein elements of FIGS. 3A-3C referred to by numerical references 3xx are similar elements of FIGS. 1A-1E referred to by numerical references 1xx, and descriptions of the elements 3xx will not be repeated.

Referring to FIGS. 3A-3C, a process flow 300 is similar to the process flow 200 of FIGS. 2A-2D except that an additional TAG is not required because an SSA 324/325 included in a layer of photoresist 327 acts as a PAG 325 that is used to generate a relief pattern 320 on a substrate 310 and acts as a TAG 324 at higher temperatures. The exposure of actinic radiation 321 (including wavelength 1) through a photomask 323 activates the PAG 325 to form a latent pattern in the layer of photoresist 327. As before, the relief pattern 320 including structures 322 separated by openings 326 is formed by developing the substrate 310 to remove the latent pattern, as illustrated in FIG. 3B. The structures 322 include the SSA 324/325 which was not activated by the actinic radiation 321 due to being shielded from the actinic radiation 321 by the photomask 323. As a result, the structures 322 are insoluble relative to a predetermined developer at this stage of the process flow 300.

As illustrated in FIG. 3C, the TAG 324 (see FIG. 3B) is activated to generate a catalyst 342 (e.g., acid) that is diffused 344 a predetermined distance 346 by applying heat 340 having a predetermined temperature T to the substrate 310 including an overcoat 330 formed over the relief pattern 320. Antispacer features are then formed by developing the substrate 310 supporting the relief pattern 320 and the overcoat 330 using the predetermined developer.

In some embodiments, the catalyst 342 (e.g., acid) can also alter the solubility of the structures 322 of the relief pattern 330 (see FIG. 3B). In such embodiments, the solubility-shifted relief pattern 330 (see FIG. 3B) remains insoluble in a predetermined developer (e.g., a negative-tone organic developer) and the soluble regions of the overcoat 330 may be selectively removed using the predetermined developer (e.g., a negative-tone organic developer) to form the antispacer features.

In this specific example, the PAG 325 functions to deprotect the photoresist upon initial light exposure and subsequent bake and develop steps to form the initial relief pattern on the substrate, but then subsequently functions as a TAG (the TAG 324) at a temperature higher than that of the relief post exposure bake (PEB).

Many example materials for the relief pattern 320 (including the SSA 324/325) and the overcoat 330, relating to the example embodiments of FIGS. 3A-3C, will be described below in the present disclosure.

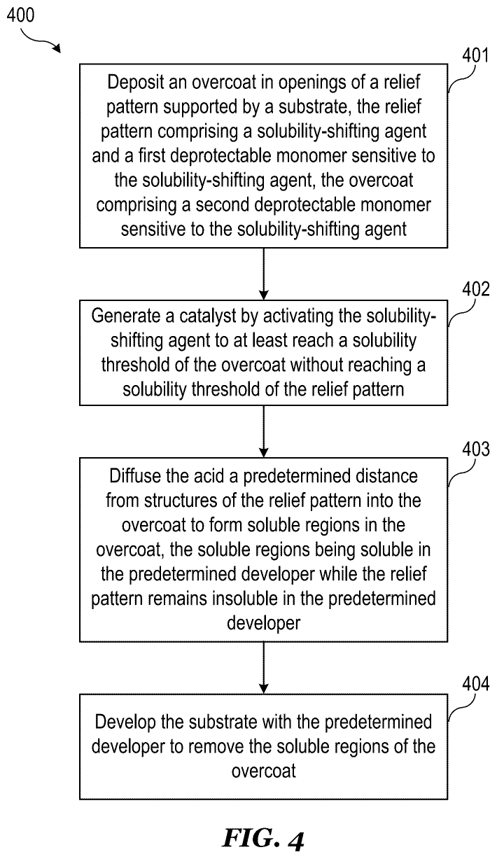

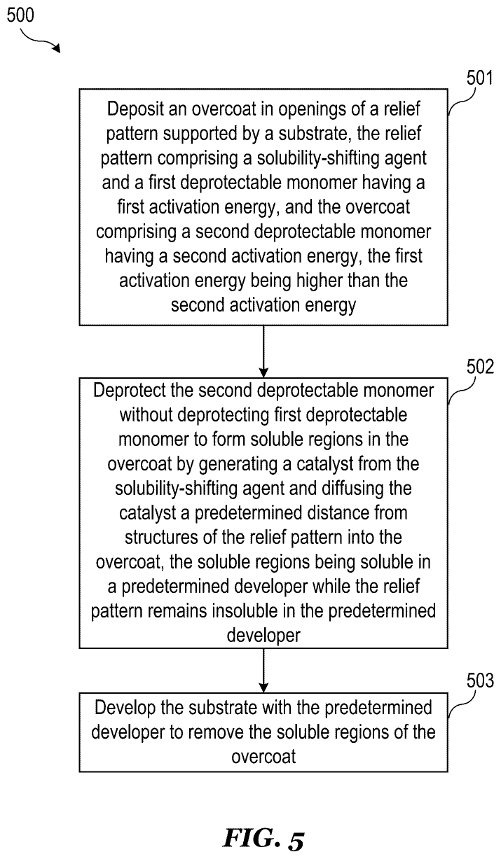

FIG. 4 illustrates an example method 400 of forming a patterned mask on a substrate in accordance with an embodiment of the present disclosure. The method 400 of FIG. 4 may be combined with other methods and performed using the systems and apparatuses as described herein. For example, the method 400 of FIG. 4 may be combined with any of the embodiments of FIGS. 1A-3C. Although shown in a logical order, the arrangement and numbering of the steps of FIG. 4 are not intended to be limiting. The method steps of FIG. 4 may be performed in any suitable order or concurrently with one another as may be apparent to a person of skill in the art.

Referring to FIG. 4, step 401 of the method 400 includes depositing an overcoat in openings of a relief pattern supported by a substrate. The relief pattern may include a solubility-shifting agent and a first deprotectable monomer sensitive to the solubility-shifting agent. The overcoat may include a second deprotectable monomer sensitive to the solubility-shifting agent. In some embodiments, the relief pattern has a first solubility threshold relative to a predetermined developer while the overcoat has a second solubility threshold relative to the predetermined developer. In an embodiment, the second solubility threshold is lower than the first solubility threshold.

Step 402 includes generating a catalyst (e.g., acid) by activating the solubility-shifting agent to at least reach the second solubility threshold of the overcoat without reaching the first solubility threshold of the relief pattern. The catalyst (e.g., acid) is diffused a predetermined distance from structures of the relief pattern into the overcoat to form soluble regions in the overcoat in step 403. The soluble regions are soluble in the predetermined developer while the relief pattern remains insoluble in the predetermined developer. In some embodiments, the catalyst (e.g., acid) does not shift the solubility of the relief pattern. In other embodiments, the catalyst (e.g., acid) shifts the solubility of the relief pattern such that the solubility-shifted relief pattern is insoluble in the predetermined developer. Steps 402 and 403 may be performed simultaneously, separately, or partially overlapping. The substrate is developed with the predetermined developer to remove the soluble regions of the overcoat in step 404.

FIG. 5 illustrates an example method 500 of forming a patterned mask on a substrate in accordance with an embodiment of the present disclosure. The method 500 of FIG. 5 may be combined with other methods and performed using the systems and apparatuses as described herein. For example, the method 500 of FIG. 5 may be combined with any of the embodiments of FIGS. 1A-3C. Additionally, the method 500 of FIG. 5 may be combined with the method 400 of FIG. 4, for example. Although shown in a logical order, the arrangement and numbering of the steps of FIG. 5 are not intended to be limiting. The method steps of FIG. 5 may be performed in any suitable order or concurrently with one another as may be apparent to a person of skill in the art.

Referring to FIG. 5, step 501 of the method 500 includes depositing an overcoat in openings of a relief pattern supported by a substrate. The relief pattern includes a solubility-shifting agent and a first deprotectable monomer having a first activation energy while the overcoat includes a second deprotectable monomer having a second activation energy. The first activation energy is higher than the second activation energy.

In step 502, the second deprotectable monomer is deprotected without deprotecting the first deprotectable monomer to form soluble regions in the overcoat by generating a catalyst (e.g., acid) from the solubility-shifting agent and diffusing the catalyst (e.g., acid) a predetermined distance from structures of the relief pattern into the overcoat. The soluble regions are soluble in a predetermined developer while the relief pattern remains insoluble in the predetermined developer. In some embodiments, the catalyst (e.g., acid) does not shift the solubility of the relief pattern. In other embodiments, the catalyst (e.g., acid) shifts the solubility of the relief pattern such that the solubility-shifted relief pattern is insoluble in the predetermined developer. The substrate is then developed with the predetermined developer to remove the soluble regions of the overcoat in step 503.

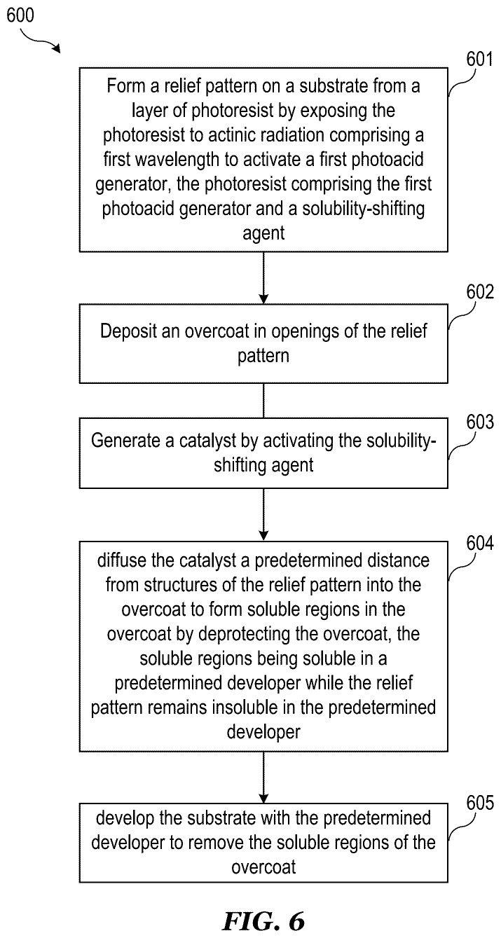

FIG. 6 illustrates an example method 600 of forming a patterned mask on a substrate in accordance with an embodiment of the present disclosure. The method 600 of FIG. 6 may be combined with other methods and performed using the systems and apparatuses as described herein. For example, the method 600 of FIG. 6 may be combined with any of the embodiments of FIGS. 1A-3C. Additionally, the method 600 of FIG. 6 may be combined with any of the methods 400 and 500 of FIGS. 4 and 5, as examples. Although shown in a logical order, the arrangement and numbering of the steps of FIG. 6 are not intended to be limiting. The method steps of FIG. 6 may be performed in any suitable order or concurrently with one another as may be apparent to a person of skill in the art.

Referring to FIG. 6, step 601 of the method 600 of patterning a substrate includes forming a relief pattern on a substrate from a layer of photoresist by exposing the photoresist to actinic radiation including a first wavelength to activate a first photoacid generator. The photoresist includes the first photoacid generator and a solubility-shifting agent. An overcoat is deposited in openings of the relief pattern in step 602.

In step 603, the solubility-shifting agent is activated to generate a catalyst (e.g., acid). Step 604 includes diffusing the catalyst (e.g., acid) a predetermined distance from structures of the relief pattern into the overcoat to form soluble regions in the overcoat by deprotecting the overcoat. The soluble regions are soluble in a predetermined developer while the relief pattern remains insoluble in the predetermined developer. In some embodiments, the catalyst (e.g., acid) does not shift the solubility of the relief pattern. In other embodiments, the catalyst (e.g., acid) shifts the solubility of the relief pattern such that the solubility-shifted relief pattern is insoluble in the predetermined developer. Steps 603 and 604 may be performed simultaneously, separately, or partially overlapping. The substrate is then developed with the predetermined developer to remove the soluble regions of the overcoat in step 605.

For describing some example materials that can be implemented and used in an embodiment of the present disclosure, some example definitions will be provided next. These definitions are intended to supplement and illustrate, not preclude, definitions known to those of skill in the art, as can be apparent to one of ordinary skill in the art to which the present disclosure pertains.

The term “independently selected” as used herein can indicate that the R groups, such as, R1, R2, R3, R4, and R5 can be identical or different (e.g., R1, R2, R3, R4, and R5 may all be substituted alkyls or R1 and R2 may be a substituted alkyl and R3 may be an aryl, etc.). Use of the singular can include use of the plural, and vice versa (e.g., a hexane solvent can include hexanes). A named R group can generally have the structure that is recognized in the art as corresponding to R groups having that name.

The term “aliphatic” can refer to a non-aromatic saturated or unsaturated straight or branched hydrocarbon radical of from 1 to 40 carbon atoms or from 1 to 18 carbon atoms.

By “substituted” as in “substituted aliphatic moiety,” “substituted aryl,” “substituted alkyl,” and “substituted alkenyl,” as alluded to in some of the aforementioned definitions, can be indicate that in the hydrocarbyl, hydrocarbylene, alkyl, alkenyl, aryl or other moiety, at least one hydrogen atom bound to a carbon atom is replaced with one or more substituents that are groups such as hydroxyl, alkoxy, alkylthio, amino, halo, and silyl, to name a few. When the term “substituted” appears prior to a list of possible substituted groups, it can be intended that the term applies to every member of that group. For example, the phrase “substituted alkyl, alkenyl, and alkynyl” can be interpreted as “substituted alkyl, substituted alkenyl, and substituted alkynyl.” Similarly, “optionally substituted alkyl, alkenyl, and alkynyl” can be interpreted as “optionally substituted alkyl, optionally substituted alkenyl, and optionally substituted alkynyl.”

The term “substitution” can indicate each hydrogen atom (H) bonded to a carbon atom or heteroatom of a corresponding unsubstituted compound or functional group is replaced by a substituent (e.g., Rs). The term “polysubstitution” can indicate each of at least two, but not all, hydrogen atoms bonded to carbon atoms or heteroatoms of a corresponding unsubstituted compound or functional group is replaced by a substituent. The (C1-C18)alkylene and (C1-C8)alkylene substituents can be especially useful for forming substituted chemical groups that are bicyclic or tricyclic analogs of corresponding monocyclic or bicyclic unsubstituted chemical groups, for example.

The term “(C1-C40)hydrocarbyl” can refer to a hydrocarbon radical of from 1 to 40 carbon atoms and the term “(C1-C40)hydrocarbylene” can refer to a hydrocarbon diradical of from 1 to 40 carbon atoms, in which each hydrocarbon radical and diradical independently is aromatic (6 carbon atoms or more) or non-aromatic, saturated or unsaturated, straight chain or branched chain, cyclic (including mono- and poly-cyclic, fused and non-fused polycyclic, including bicyclic; 3 carbon atoms or more) or acyclic, or a combination of two or more thereof, and each hydrocarbon radical and diradical independently can be the same as or different from another hydrocarbon radical and diradical, respectively, and independently can be unsubstituted or substituted by one or more Rs.

In the present disclosure, a (C1-C40)hydrocarbyl independently can be an unsubstituted or substituted (C1-C40)alkyl, (C3-C40)cycloalkyl, (C3-C20)cycloalkyl-(C1-C20)alkylene, (C6-C40)aryl, or (C6-C20)aryl-(C1-C20)alkylene. In some embodiments, each of the aforementioned (C1-C40)hydrocarbyl groups independently has a maximum of 20 carbon atoms (i.e., (C1-C20)hydrocarbyl) and in other embodiments, a maximum of 12 carbon atoms, for example.

The terms “(C1-C40)alkyl” and “(C1-C18)alkyl” can refer to a saturated straight or branched hydrocarbon radical of from 1 to 40 carbon atoms or from 1 to 18 carbon atoms, respectively, that is unsubstituted or substituted by one or more Rs. Examples of unsubstituted (C1-C40)alkyl are: unsubstituted (C1-C20)alkyl; unsubstituted (C1-C10)alkyl; unsubstituted (C1-C5)alkyl; methyl; ethyl; 1-propyl; 2-propyl; 1-butyl; 2-butyl; 2-methylpropyl; 1,1-dimethylethyl; 1-pentyl; 1-hexyl; 1-heptyl; 1-nonyl; and 1-decyl. Examples of substituted (C1-C40)alkyl are substituted (C1-C20)alkyl, substituted (C1-C10)alkyl, trifluoromethyl, and (C45)alkyl. The (C45)alkyl is, for example, a (C27-C40)alkyl substituted by one Rs, which is a (C1-C5)alkyl, respectively. In some embodiments, each (C1-C5)alkyl independently is methyl, trifluoromethyl, ethyl, 1-propyl, 1-methylethyl, or 1,1-dimethylethyl, for example.

The term “(C6-C40)aryl” can refer to an unsubstituted or substituted (by one or more Rs) mono-, bi-, or tricyclic aromatic hydrocarbon radical of from 6 to 40 carbon atoms, of which at least from 6 to 14 of the carbon atoms are aromatic ring carbon atoms, and the mono-, bi-, or tricyclic radical comprises 1, 2 or 3 rings, respectively; wherein the 1 ring is aromatic and the 2 or 3 rings independently are fused or non-fused and at least one of the 2 or 3 rings is aromatic. Examples of unsubstituted (C6-C40)aryl are: unsubstituted (C6-C20)aryl unsubstituted (C6-C18)aryl; 2-(C1-C5)alkyl-phenyl; 2,4-bis(C1-C5)alkyl-phenyl; phenyl; fluorenyl; tetrahydrofluorenyl; indacenyl; hexahydroindacenyl; indenyl; dihydroindenyl; naphthyl; tetrahydronaphthyl; and phenanthrene. Examples of substituted (C6-C40)aryl are: substituted (C1-C20)aryl; substituted (C6-C18)aryl; 2,4-bis[(C20)alkyl]-phenyl; polyfluorophenyl; pentafluorophenyl; and fluoren-9-one-1-yl.

The term “(C3-C40)cycloalkyl” can refer to a saturated cyclic hydrocarbon radical of from 3 to 40 carbon atoms that is unsubstituted or substituted by one or more Rs. Other cycloalkyl groups (e.g., (C3-C12)alkyl) can be defined in an analogous manner. Examples of unsubstituted (C3-C40)cycloalkyl are: unsubstituted (C3-C20)cycloalkyl, unsubstituted (C3-C10)cycloalkyl, cyclopropyl, cyclobutyl, cyclopentyl, cyclohexyl, cycloheptyl, cyclooctyl, cyclononyl, and cyclodecyl. Examples of substituted (C3-C40)cycloalkyl are: substituted (C3-C20)cycloalkyl, substituted (C3-C10)cycloalkyl, cyclopentanon-2-yl, and 1-fluorocyclohexyl.

Examples of (C1-C40)hydrocarbylene are: unsubstituted or substituted (C6-C40)arylene, (C3-C40)cycloalkylene, and (C1-C40)alkylene (e.g., (C1-C20)alkylene). In some embodiments, the diradicals are a same carbon atom (e.g., —CH2—) or on adjacent carbon atoms (i.e., 1,2-diradicals), or are spaced apart by one, two, or more intervening carbon atoms (e.g., respective 1,3-diradicals, 1,4-diradicals, etc.), for example. Some embodiments incorporate a 1,2-, 1,3-, 1,4-, or an alpha, omega-diradical, and others a 1,2-diradical, for example. The alpha, omega-diradical can be a diradical that has maximum carbon backbone spacing between the radical carbons. Some embodiments can incorporate a 1,2-diradical, 1,3-diradical, or 1,4-diradical version of (C6-C18)arylene, (C3-C20)cycloalkylene, or (C2-C20)alkylene.

The term “(C1-C40)alkylene” can refer to a saturated straight chain or branched chain diradicals (i.e., the radicals are not on ring atoms) of from 1 to 40 carbon atoms that is unsubstituted or substituted by one or more Rs. Examples of unsubstituted (C1-C40)alkylene are: unsubstituted (C1-C20)alkylene, including unsubstituted 1,2-(C2-C10)alkylene; including unsubstituted 1,3-(C3-C10)alkylene; 1,4-(C4-C10)alkylene; —C—, —CH2CH2-, —(CH2)—, —CH2CHCH3, —(CH2)4-, —(CH2)5-, —(CH2)6-, —(CH2)7-, —(CH2)8-, and —(CH2)4C(H) (CH3)—.

Examples of substituted (C1-C40)alkylene are: substituted (C1-C20)alkylene, —CF2-, —C(O)—, and —(CH2)14C(CH3)2 (CH2)5-(i.e., a 6,6-dimethyl substituted normal-1,20-eicosylene). As mentioned previously two Rs may be taken together to form a (C1-C18)alkylene, examples of substituted (C1-C40)alkylene also include 1,2-bis(methylene)cyclopentane, 1,2-bis(methylene)cyclohexane, 2,3-bis(methylene)-7,7-dimethyl-bicyclo[2.2.1]heptane, and 7,3-bis(methylene) bicyclo[2.2.2]octane.

The term “(C3-C40)cycloalkylene” can refer to a cyclic diradical (i.e., the radicals are on ring atoms) of from 3 to 40 carbon atoms that is unsubstituted or substituted by one or more Rs.

The term “heteroatom,” “heterohydrocarbon′ can refer to a molecule or molecular framework in which one or more carbon atoms are replaced with an atom other than carbon or hydrogen. The term “(C1-C40) heterohydrocarbyl” can refer to a heterohydrocarbon radical of from 1 to 40 carbon atoms and the term “(C1-C40) heterohydrocarbylene” can refer to a heterohydrocarbon diradical of from 1 to 40 carbon atoms, and each heterohydrocarbon independently has one or more heteroatoms, for example O, S, S(O), S(O)2, Si(RC)2, P(RP), and N(RN). Independently each RC is unsubstituted (C1-C18)hydrocarbyl, each RP is unsubstituted (C1-C19)hydrocarbyl, and each RN is unsubstituted (C1-C18)hydrocarbyl or absent. When RN is absent then N comprises —N═. The heterohydrocarbon radical, and each of the heterohydrocarbon diradicals, independently is on a carbon atom or heteroatom thereof, and in most embodiments, it is on a carbon atom when bonded to a heteroatom formula (I) or to a heteroatom of another heterohydrocarbyl or heterohydrocarbylene. Each (C1-C40) heterohydrocarbyl and (C1-C40) heterohydrocarbylene independently is unsubstituted or substituted (by one or more Rs), aromatic or non-aromatic, saturated or unsaturated, straight chain or branched chain, cyclic (including mono- and poly-cyclic, fused and non-fused polycyclic) or acyclic, or a combination of two or more thereof; and each is respectively the same as or different from another.

In some embodiments, the (C1-C40) heterohydrocarbyl independently can be unsubstituted or substituted (C1-C40) heteroalkyl, (C1-C40)hydrocarbyl-O—, (C1-C40)hydrocarbyl-S—, (C1-C40)hydrocarbyl-S(O)—, (C1-C40)hydrocarbyl-S(O) 2-, (C1-C40)hydrocarbyl-Si(Rc) 2-, (C1-C40)hydrocarbyl-N(RN)—, (C1-C40)hydrocarbyl-P(RP)—, (C2-C40) heterocycloalkyl, (C2-C19) heterocycloalkyl-(C1-C20)alkylene, (C3-C20cycloalkyl-(C1-C19) heteroalkylene, (C2-C19) heterocycloalkyl-(C1-C20) heteroalkylene, (C1-C40) heteroaryl, (C1-C19) heteroaryl-(C₁-C₂₀)alkylene, (C6-C20)aryl-(C1-C19) heteroalkylene, or (C1-C19) heteroaryl-(C1-C20) heteroalkylene, for example.

The term “(C4-C40) heteroaryl” can refer to an unsubstituted or substituted (by one or more Rs) mono-, bi-, or tricyclic heteroaromatic hydrocarbon radical of from 1 to 40 total carbon atoms and from 1 to 4 heteroatoms, and the mono-, bi-, or tricyclic radical can include 1, 2, or 3 rings, respectively, wherein the 2 or 3 rings independently can be fused or non-fused and at least one of the 2 or 3 rings can be heteroaromatic. Other heteroaryl groups (e.g., (C4-C12) heteroaryl) can be defined in an analogous manner. The monocyclic heteroaromatic hydrocarbon radical can be a 5-membered or 6-membered ring. The 5-membered ring can have from 2 to 4 carbon atoms and from 3 to 1 heteroatoms, respectively, each heteroatom being O, S, N, or P. Examples of 5-membered ring heteroaromatic hydrocarbon radical are: pyrrol-1-yl; pyrrol-2-yl; furan-3-yl; thiophen-2-yl; pyrazol-1-yl; isoxazol-2-yl; isothiazol-5-yl; imidazol-2-yl; oxazol-4-yl; thiazol-2-yl; 1,2,4-triazol-1-yl; 1,3,4-oxadiazol-2-yl; 1,3,4-thiadiazol-2-yl; tetrazol-1-yl; tetrazol-2-yl; and tetrazol-5-yl. The 6-membered ring can have 4 or 5 carbon atoms and 2 or 1 heteroatoms, the heteroatoms being N or P. Examples of 6-membered ring heteroaromatic hydrocarbon radical are: pyridine-2-yl; pyrimidin-2-yl; and pyrazin-2-yl. The bicyclic heteroaromatic hydrocarbon radical can be a fused 5,6- or 6,6-ring system. Examples of the fused 5,6-ring system bicyclic heteroaromatic hydrocarbon radical are: indol-1-yl; and benzimidazole-1-yl. Examples of the fused 6,6-ring system bicyclic heteroaromatic hydrocarbon radical are: quinolin-2-yl; and isoquinolin-1-yl. The tricyclic heteroaromatic hydrocarbon radical can be a fused 5,6,5-; 5,6,6-; 6,5,6-; or 6,6,6-ring system. An example of the fused 5,6,5-ring system is 1,7-dihydropyrrolo[3,2-f]indol-1-yl. An example of the fused 5,6,6-ring system is 1H-benzo[f]indol-1-yl. An example of the fused 6,5,6-ring system is 9H-carbazol-9-yl. An example of the fused 6,5,6-ring system is 9H-carbazol-9-yl. An example of the fused 6,6,6-ring system is acrydin-9-yl.

The aforementioned heteroalkyl and heteroalkylene groups can be saturated straight or branched chain radicals or diradicals, respectively, containing (C1-C40) carbon atoms, or fewer carbon atoms and one or more of the heteroatoms Si(Rc)2, P(RP), N(RN), N, O, S, S(O), and S(O)2 as defined above, wherein each of the heteroalkyl and heteroalkylene groups independently can be unsubstituted or substituted by one or more Rs.

Examples of unsubstituted (C2-C40) heterocycloalkyl are: unsubstituted (C2-C20) heterocycloalkyl, unsubstituted (C2-C10) heterocycloalkyl, aziridin-1-yl, oxetan-2-yl, tetrahydrofuran-3-yl, pyrrolidin-1-yl, tetrahydrothiophen-S,S-dioxide-2-yl, morpholin-4-yl, 1,4-dioxan-2-yl, hexahydroazepin-4-yl, 3-oxa-cycloodyl, 5-thio-cyclononyl, and 2-aza-cyclodecyl.

The term “halogen atom” can refer to fluorine atom (F), chlorine atom (CI), bromine atom (Br), or iodine atom (I) radical. The terms “halide” can refer to fluoride (F—), chloride (Cl—), bromide (Br—), or iodide (I—) anion.

The term “saturated” can refer to lacking carbon-carbon double bonds, carbon-carbon triple bonds, and (in heteroatom-containing groups) carbon-nitrogen, carbon-phosphorous, and carbon-silicon double bonds. Where a saturated chemical group is substituted by one or more substituents Rs, one or more double and/or triple bonds optionally may or may not be present in substituents Rs. The term “unsaturated” can refer to containing one or more carbon-carbon double bonds, carbon-carbon bonds, and (in heteroatom-containing groups) carbon-nitrogen, carbon-phosphorous, and carbon-silicon double bonds, not including any such double bonds that may be present in substituents Rs, if any, or in (hetero) aromatic rings, if any.

### Relief Pattern Composition

In an embodiment of present disclosure, a relief pattern composition of a relief pattern (e.g., relief patterns 120, 220, and 320 of FIGS. 1A, 2A, and 3A, respectively) can be a composition that can include a first polymer, an SSA (e.g., SSA 124 of FIG. 1A, TAG 224 and PAG 225 of FIG. 2A, or SSA 324/325 of FIG. 3A), a solvent, and may also contain additional, optional components.

### First Polymer

In an embodiment, the first polymer of the relief pattern composition may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the —OH group of p-hydroxystyrene may be protected with a tert-butyloxycarbonyl protecting group. Such protecting group may alter the reactivity and solubility of the polymer included in the relief pattern. As will be appreciated by one having ordinary skill in the art, various protecting groups may be used for this reason. Acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The acid-labile group which, on decomposition, forms a carboxylic acid on the polymer is preferably a tertiary ester group of the formula —C(O)OC(R¹) s or an acetal group of the formula —C(O)OC(R²)2OR³, wherein: R¹ is each independently linear Ci-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably linear C 1-6 alkyl, branched C3-6 alkyl, or monocyclic or polycyclic C3-10 cycloalkyl, each of which is substituted or unsubstituted, each R¹ optionally including as part of its structure one or more groups chosen from —O—, —C(O)—, —C(O)—O—, or —S—, and any two R¹ groups together optionally forming a ring; R² is independently hydrogen, fluorine, linear C 1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably hydrogen, linear C 1-6 alkyl, branched C3-6 alkyl, or monocyclic or polycyclic C3-10 cycloalkyl, each of which is substituted or unsubstituted, each R² optionally including as part of its structure one or more groups chosen from —O—, —C(O)—, —C(O) —O—, or —S—, and the R² groups together optionally forming a ring; and R³ is linear Ci-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C&-20 aryl, or monocyclic or polycyclic C2-20 heteroaryl, preferably linear C 1-6 alkyl, branched C3-6 alkyl, or monocyclic or polycyclic C3-10 cycloalkyl, each of which is substituted or unsubstituted, R³ optionally including as part of its structure one or more groups chosen from O—, —C(O)—, —C(O)—O—, or —S—, and one R² together with R³ optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

The first polymer can further include as polymerized a monomer comprising an acid-labile group, the decomposition of which group forms an alcohol group or a fluoroalcohol group on the polymer. Suitable such groups include, for example, an acetal group of the formula COC(R²)2OR³—, or a carbonate ester group of the formula-OC(O)O—, wherein R is as defined above. Such monomer is typically a vinyl aromatic, (meth)acrylate, or norbornyl monomer. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

### Solubility Shifting Agent

Next, some example materials that can be implemented and used for a solubility shifting agent (e.g., SSA 124 of FIG. 1A, TAG 224 and PAG 225 of FIG. 2A, or SSA 324/325 of FIG. 3A) will be described.

### Solubility Shifting Agent as Free Acid

In some embodiments, an SSA can be an acid that is an organic acid, which can include both non-aromatic acids and aromatic acids optionally having fluorine substitution. Suitable organic acids for the SSA of an embodiment can include: carboxylic acids and polycarboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid, and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1 perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid; or any combination thereof, for example.

In some embodiments, an SSA can be an aromatic sulfonic acid. For example, an aromatic sulfonic acid can be of general Formula 4:

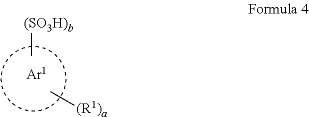

In Formula 4, Ar¹ can represent an aromatic group, which can be carbocyclic, heterocyclic, or a combination thereof. The aromatic group can be monocyclic, for example, phenyl or pyridyl, or polycyclic, for example biphenyl, and can include: plural fused aromatic rings such as naphthyl, anthracenyl, pyrenyl, or quinolinyl; or fused ring systems having both aromatic and non-aromatic rings such as 1,2,3,4-tetrahydronaphthalene, 9,10-dihydroanthracene or fluorene. A wide variety of aromatic groups may be used for Ar¹. The aromatic group typically can have from 5 to 40 carbons, preferably from 6 to 35 carbons, and more preferably from 6 to 30 carbons. Suitable aromatic groups can include, but are not limited to: phenyl, biphenyl, naphthalenyl, anthracenyl, phenanthrenyl, pyrenyl, tetracenyl, triphenylenyl, tetraphenyl, benzo[f]tetraphenyl, benzo[m]tetraphenyl, benzo[k]tetraphenyl, pentacenyl, perylenyl, benzo[a]pyrenyl, benzo[e]pyrenyl, benzo[ghi]perylenyl, coronenyl, quinolonyl, 7,8-benzoquinolinyl, fluorenyl, and 12H-dibenzo[b,h]fluorenyl. Of these, phenyl can be particularly preferred.

In Formula 4, R¹ independently can represent a halogen atom, hydroxy, substituted or unsubstituted alkyl, substituted or unsubstituted heteroalkyl, substituted or unsubstituted carbocyclic aryl, substituted or unsubstituted heterocyclic aryl, substituted or unsubstituted alkoxy, or a combination thereof. R¹ can also include one or more groups such as ester, carboxy, ether, or a combination thereof.

In Formula 4, “a” can represent an integer of 0 or more and “b” can represent an integer of 1 or more, provided that a+b is not greater than the total number of available aromatic carbon atoms of Ar¹. Preferably, two or more of R¹ can be independently a fluorine atom or a fluoroalkyl group bonded directly to an aromatic ring carbon atom.

The aromatic acid can be a sulfonic acid including a phenyl, biphenyl, naphthyl, anthracenyl, thiophene or furan group. The aromatic acid can be chosen from one or more aromatic sulfonic acids of the following general Formulas 5-10:

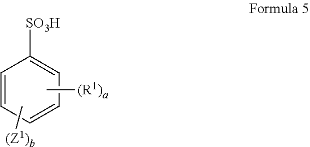

In Formula 5, R1 can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 5, Z¹ can independently represent a group chosen from carboxyl, hydroxy, nitro, cyano, C1 to C5 alkoxy, formyl and sulfonic acid. In Formula 5, “a” and “b” can be independently an integer from 0 to 5, and a+b can be 5 or less.

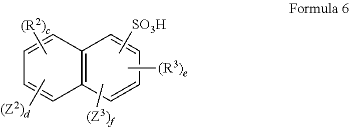

In Formula 6, R² and R³ each can independently represent a substituted or unsubstituted C1-C20 alkyl group, a substituted or unsubstituted C5-C16 aryl group, or a combination thereof, optionally containing one or more group chosen from carbonyl, carbonyloxy, sulfonamido, ether, thioether, a substituted or unsubstituted alkylene group, or a combination thereof.

In Formula 6, Z² and Z³ each can independently represent a group chosen from carboxyl, hydroxy, nitro, cyano, C1 to C5 alkoxy, formyl and sulfonic acid. In Formula 6, “c” and “d” can be independently an integer from 0 to 4, c+d can be 4 or less, “e” and “f” can be independently an integer from 0 to 3, and e+f can be 3 or less.

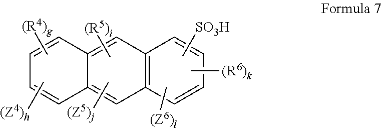

In Formula 7, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof

In Formula 7, Z⁴, Z⁵ and Z⁶ each can independently represent a group chosen from carboxyl, hydroxy, nitro, cyano, C1 to C5 alkoxy, formyl and sulfonic acid. In Formula 7, “g” and “h” can be independently an integer from 0 to 4, g+h can be 4 or less, “i” and “j” can be independently an integer from 0 to 2, i+j can be 2 or less, “k” and “1” can be independently an integer from 0 to 3, and k+l can be 3 or less.

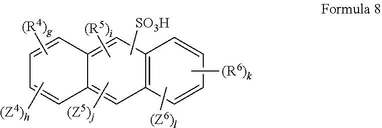

In Formula 8, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof.

In Formula 8, Z⁴, Z⁵ and Z⁶ each can independently represent a group chosen from carboxyl, hydroxy, nitro, cyano, C1 to C5 alkoxy, formyl and sulfonic acid. In Formula 8, “g” and “h” can be independently an integer from 0 to 4, g+h can be 4 or less, “i” and “j” can be independently an integer from 0 to 1, i+j can be 1 or less, “k” and “1” can be independently an integer from 0 to 4, and k+1 can be 4 or less.

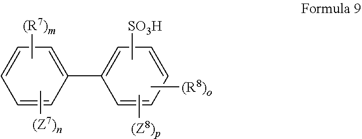

In Formula 9, R⁷ and R⁸ each can independently represent a substituted or unsubstituted C1-C20 alkyl group, a substituted or unsubstituted C5-C14 aryl group, or a combination thereof, optionally containing one or more group chosen from carboxyl, carbonyl, carbonyloxy, sulfonamido, ether, thioether, a substituted or unsubstituted alkylene group, or a combination thereof

In Formula 9, Z⁷ and Z⁸ each can independently represent a group chosen from hydroxy, nitro, cyano, C1 to C5 alkoxy, formyl and sulfonic acid. In Formula 9, “m” and “n” can be independently an integer from 0 to 5, m+n can be 5 or less, “o” and “p” can be independently an integer from 0 to 4, and o+p can be 4 or less.

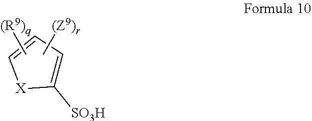

In Formula 10, X can be O or S. In Formula 10, R⁹ can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 10, Z⁹ can independently represent a group chosen from carboxyl, hydroxy, nitro, cyano, C1 to C5 alkoxy, formyl and sulfonic acid. In Formula 10, “q” and “r” can be independently an integer from 0 to 3, and q+r can be 3 or less.

For each of the structures of Formulas 5-10, the R¹—R⁹ groups can optionally form a fused structure together with their respective associated rings, for example.

For an SSA of an embodiment, example aromatic sulfonic acids can include, without limitation, the following:

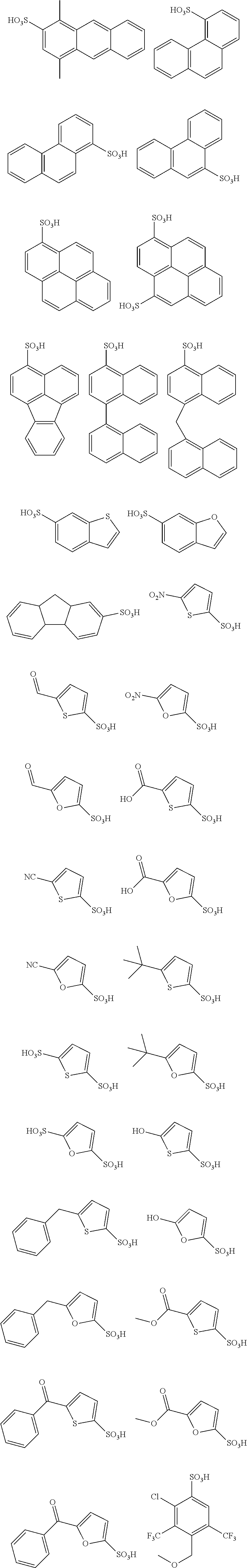

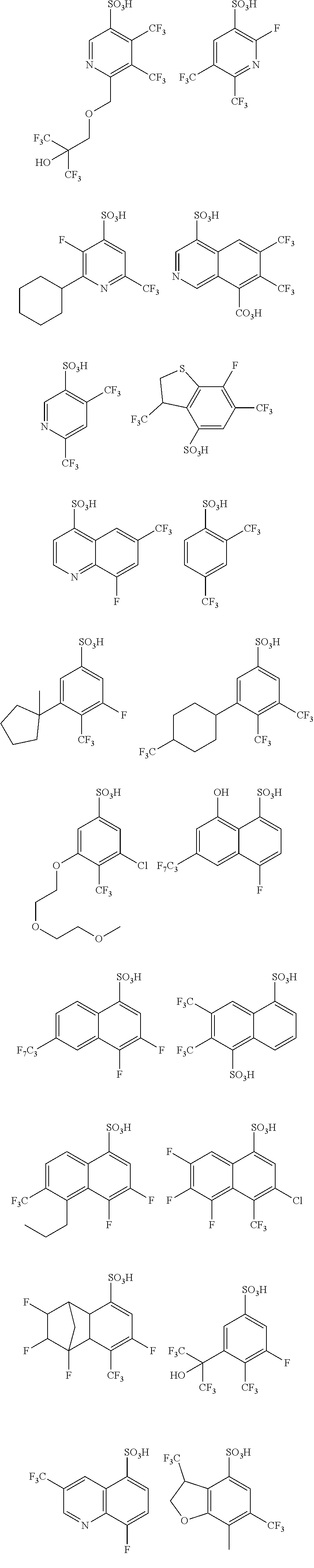

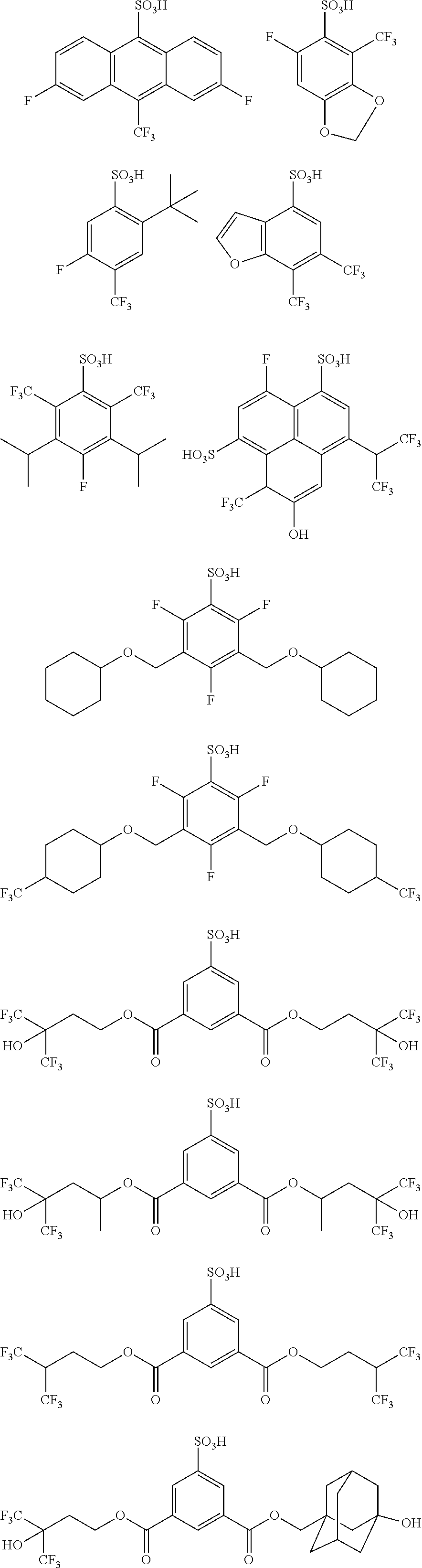

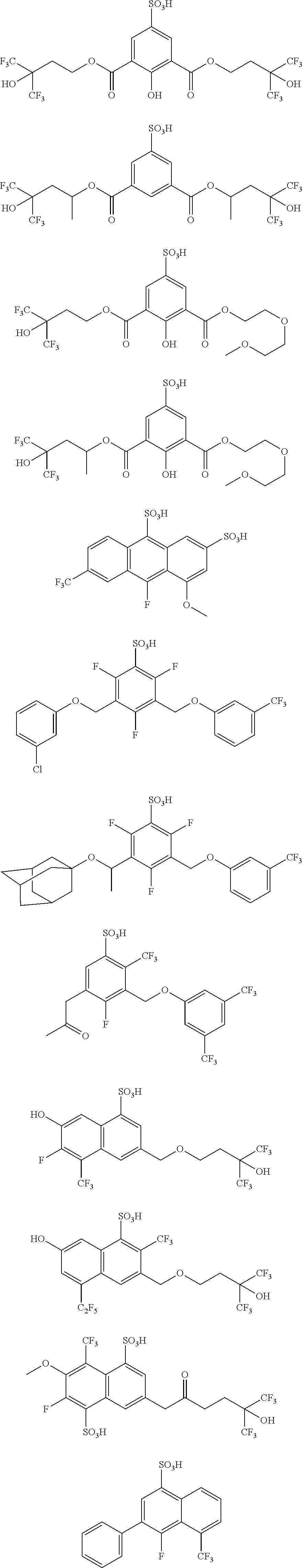

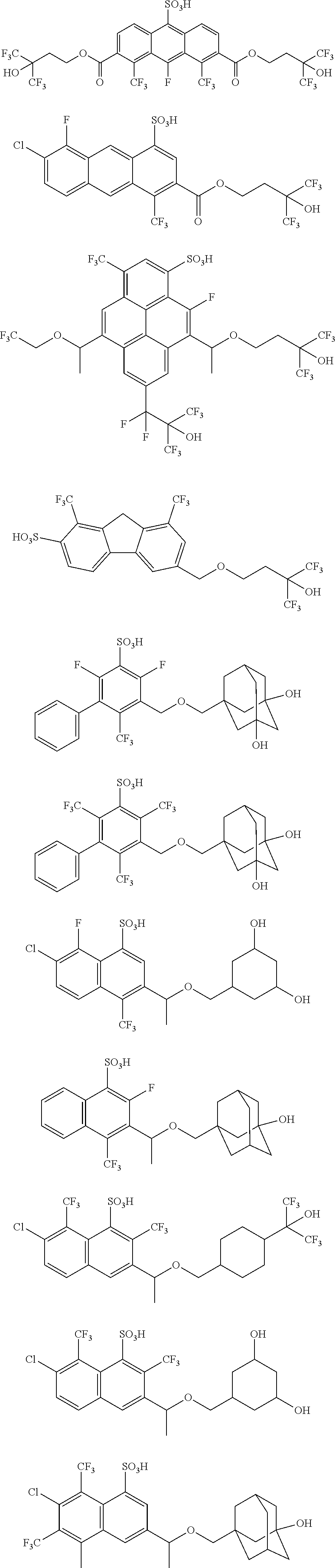

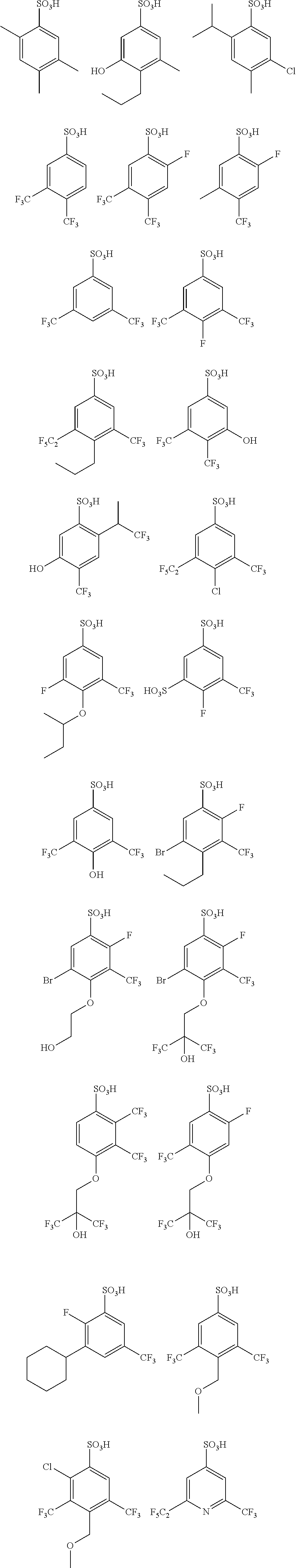

For an SSA of an embodiment, example non-aromatic sulfonic acids can include, without limitation, the following:

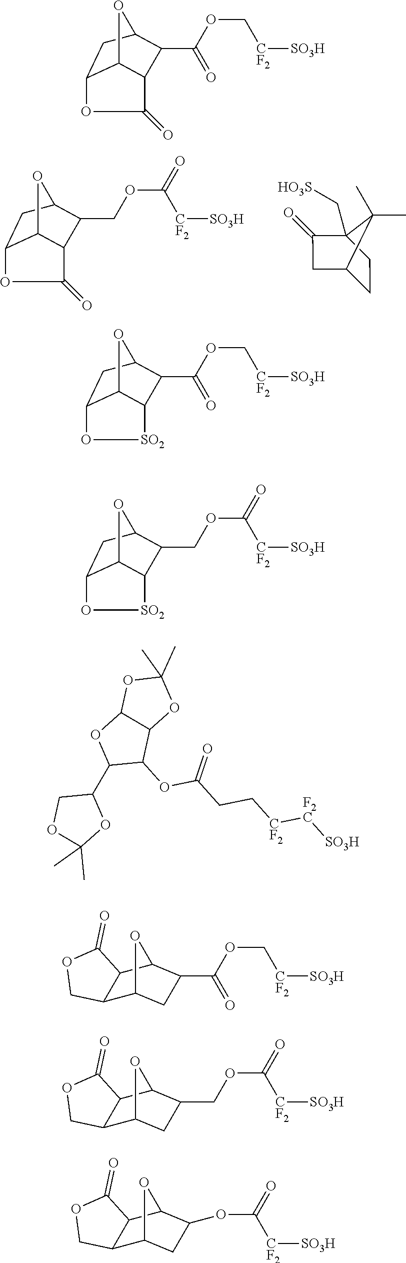

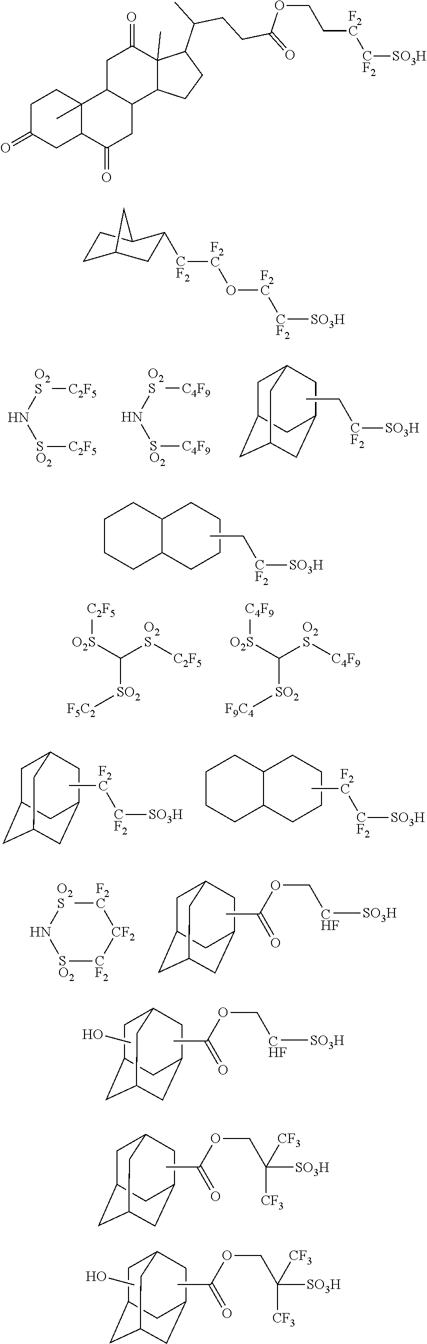

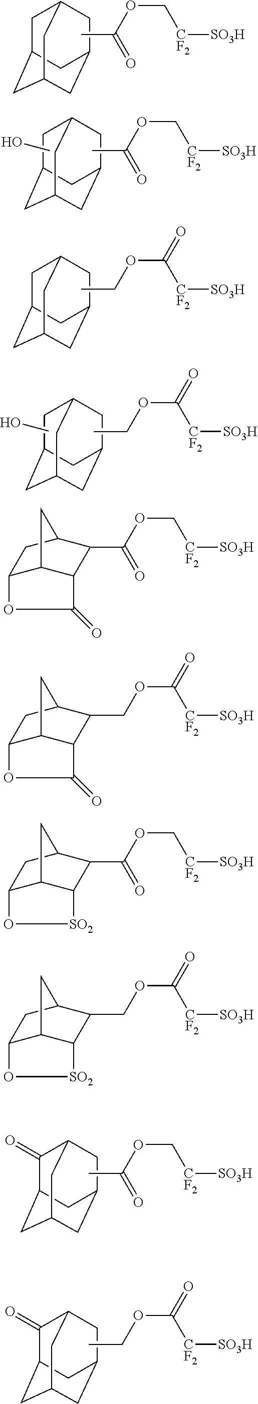

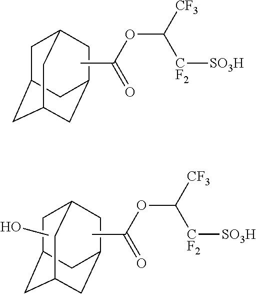

### Solubility Shifting Agent as Thermal Acid Generator (TAG)

For an SSA of an embodiment, suitable thermal acid generators can include those capable of generating the acids described above. The thermal acid generator (TAG) can be non-ionic or ionic.

For an SSA of an embodiment, suitable nonionic thermal acid generators can include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1, 3, 5-triazine-2, 4, 6-trione, alkyl esters of organic sulfonic acids, p-toluenesulfonic acid, dodecylbenzenesulfonic acid, oxalic acid, phthalic acid, phosphoric acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, or their salts, or combinations thereof.

For an SSA of an embodiment, suitable ionic thermal acid generators can include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, or benzenesulfonate salts, or combinations thereof. Compounds that can generate a sulfonic acid upon activation can be generally suitable as a TAG for an SSA of an embodiment, for example. For an SSA of an embodiment, some preferred thermal acid generators can include p-toluenesulfonic acid ammonium salts and heteroaryl sulfonate salts, for example.

For example, for an SSA of an embodiment, the TAG can be preferably ionic with the Formula 11:

(BH)⁺X⁻ Formula 11

where X⁻ may selected from sulfonate, phosphonate, and sulfamate:

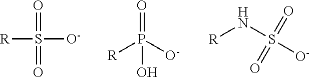

and R is alkyl or aryl.

In Formula 11, suitable nitrogen-containing bases B can include, for example, optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; and nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B can be preferably a heteroaromatic base.

Base B typically can have a pKₐ from 0 to 5.0, or between 0 and 4.0, or between 0 and 3.0, or between 1.0 and 3.0. As used herein, the term “pKₐ” is used in accordance with its art-recognized meaning, that is, pKₐ can be the negative log (to the base 10) of the dissociation constant of the conjugate acid (BH)⁺ of the basic moiety (B) in aqueous solution at about room temperature. In certain embodiments, base B can have a boiling point less than about 170° C., or less than about 160° C., 150° C., 140° C., 130° C., 120° C., 110° C., 100° C., or 90° C.

In an embodiment, the suitable nitrogen-containing bases B can also include the following:

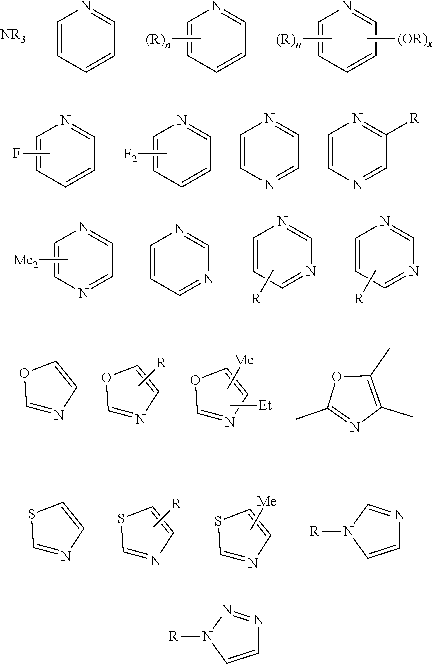

where R is alkyl or aryl.

For example, for an SSA of an embodiment, the TAG can be preferably ionic with the Formula 12:

(M)⁺X⁻ Formula 12

where M⁺ is an organic cation and X⁻ is same as in the Formula 11.

In an embodiment, the organic cation M⁺ can include the following:

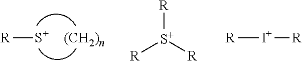

where R is alkyl or aryl.

For example, for an SSA of an embodiment, the TAG of the Formula 12 can include the following:

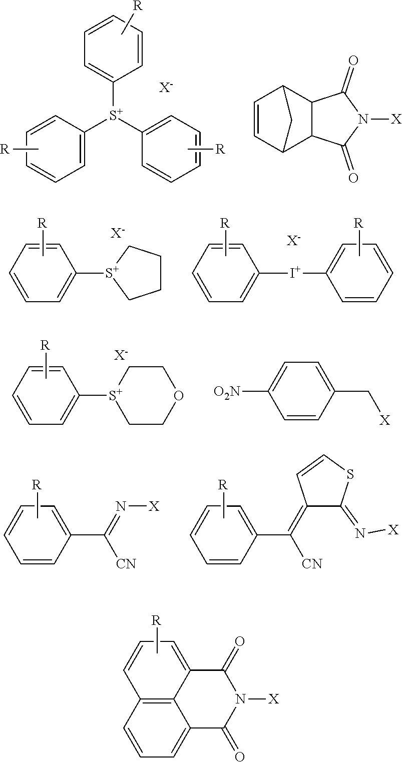

where R is alkyl or aryl.

### Solubility Shifting Agent as Photoacid Generator (PAG)

For an SSA of an embodiment, suitable photoacid generators can include those capable of generating the acids described above. For an SSA of an embodiment, a photoacid generator which can be used may be appropriately selected from a photoinitiator for photocationic polymerization, a photoinitiator for photoradical polymerization, a photo-decoloring agent for coloring matters, a photo-discoloring agent, a known compound used for microresist, or the like, and capable of generating an acid upon irradiation with actinic rays or radiation, and mixtures thereof, for example.

For an SSA of an embodiment, a choice of PAG can be based upon such factors as acidity, catalytic activity, volatility, diffusivity, and solubility. For an SSA of an embodiment, examples of embodied photoacid generators can include a diazonium salt, a phosphonium salt, a sulfonium salt, an iodonium salt, an imidosulfonate, an oxime sulfonate, a diazodisulfone, a disulfone, or an o-nitrobenzyl sulfonate, for example.

For an SSA of an embodiment, suitable classes of PAGs generating sulfonic acids can include, but are not limited to, sulfonium or iodonium salts, oximidosulfonates, bissulfonyldiazomethanes, and nitrobenzylsulfonate esters, for example. For an SSA of an embodiment, a PAG can be in non-polymerized or polymeric form, for example, present in a polymerized repeating unit of the polymer matrix. For an SSA of an embodiment, suitable photoacid generator compounds are disclosed, for example, in U.S. Pat. Nos. 5,558,978, 5,468,589, 6,844,132, 6,855,476, and 6,911,297, which are incorporated herein by reference in their entireties. In some embodiments, a preferred PAGs can include one or more of tris(perfluoroalkylsulfonyl) methides, tris(perfluoroalkylsulfonyl) imides, and those generating perfluoroalkylsulfonic acids, for example.

For an SSA of an embodiment, additional examples of suitable photoacid generators can include, but are not limited to, triphenylsulfonium perfluorooctanesulfonate, triphenylsulfonium perfluorobutanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl) sulfonium perfluorooctanesulfonate, tris(-t-butylphenyl) sulfonium perfluorobutanesulfonate, tris(-t-butylphenyl) sulfonium 2,4,6-triisopropylbenzenesulfonate, tris(-t-butylphenyl) sulfonium benzenesulfonate, and phenylthiophenyldiphenylsulfonium perfluorooctanesulfonate.

For an SSA of an embodiment, examples of suitable iodonium salts can include, but are not limited to, diphenyl iodonium perfluorobutanesulfonate, bis-(t-butylphenyl) iodonium perfluorobutanesulfonate, bis-(t-butylphenyl) iodonium, perfluorooctanesulfonate, diphenyl iodonium perfluorooctanesulfonate, bis-(t-butylphenyl) iodonium benzenesulfonate, bis-(t-butylphenyl) iodonium 2,4,6-triisopropylbenzenesulfonate, and diphenyliodonium 4-methoxybenzensulfonate.

For an SSA of an embodiment, examples of tris(perfluoroalkylsulfonyl) methide and tris(perfluoroalkylsulfonyl) imide PAGs can be found in U.S. Pat. Nos. 5,554,664 and 6,306,555, each of which is incorporated herein in its entirety. For an SSA of an embodiment, additional examples of PAGs of this type can be found in Proceedings of SPIE, Vol. 4690, pp. 817-828 (2002).

For an SSA of an embodiment, suitable methide and imide PAGs can include, but are not limited to, triphenylsulfonium tris(trifluoromethylsulfonyl) methide, methylphenyldiphenylsulfonium tris(perfluoroethylsulfonyl) methide, triphenylsulfonium tris(perfluorobutylsulfonyl) methide, triphenylsulfonium bis(trifluoromethylsulfonyl)imide, triphenylsulfonium bis(perfluoroethylsulfonyl)imide, and triphenylsulfonium bis(perfluorobutylsulfonyl)imide.

For an SSA of an embodiment, further examples of suitable photoacid generators can be bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl) propiophenone, 2-methanesulfonyl-2-methyl-(4-methylthiopropiophenone, 2,4-methyl-2-(p-toluenesulfonyl) pent-3-one, 1-diazo-1-methylsulfonyl-4-phenyl-2-butanone, 2-(cyclohexylcarbonyl-2-(p-toluenesulfonyl) propane, 1-cyclohexylsulfonyl-1cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, and 2,4-dinitrobenzyl p-trifluoromethylbenzenesulfonate.

For an SSA of an embodiment, some more preferred PAGs can be triarylsulfonium perfluoroalkylsulfonates and triarylsulfonium tris(perfluoroalkylsulfonyl) methides. For an SSA of an embodiment, some more preferred PAGs can include triphenylsulfonium perfluorooctanesulfonate (TPS-PFOS), triphenylsulfonium perfluorobutanesulfonate (TPS-Nonaflate), methyiphenyldiphenylsulfonium perfluorooctanesulfonate (TDPS-PFOS), tris(-t-butylphenyl) sulfonium perfluorobutanesulfonate (TTBPS-Nonaflate), triphenylsulfonium tris(trifluoromethylsulfonyl) methide (TPS-C1), or methylphenyldiphenylsulfonium tris(perfluoroethylsulfonyl) methide.

For an SSA of an embodiment, additional PAG compounds can include, for example: onium salts, for example, triphenylsulfonium trifluoromethanesulfonate, (p-tert-butoxyphenyl)diphenylsulfonium trifluoromethanesulfonate, tris(p-tert-butoxyphenyl) sulfonium trifluoromethanesulfonate, triphenylsulfonium p-toluenesulfonate; di-t-butyphenyliodonium perfluorobutanesulfonate, or di-t-butyphenyliodonium camphorsulfonate.

For an SSA of an embodiment, non-ionic sulfonates and sulfonyl compounds can function as photoacid generators, for example: nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-a-dimethylglyoxime, and bis-O-(n-butanesulfonyl)-a-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; or halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

For an SSA of an embodiment, suitable non-polymerized photoacid generators that can be used are further described in U.S. Pat. No. 8,431,325 to Hashimoto et al. in column 37, lines 11-47 and columns 41-91. For an SSA of an embodiment, other suitable sulfonate PAGs can include sulfonated esters and sulfonyloxy ketones, nitrobenzyl esters, s-triazine derivatives, benzoin tosylate, t-butylphenyl a-(p-toluenesulfonyloxy)-acetate, and t-butyl a-(p-toluenesulfonyloxy)-acetate; as described in U.S. Pat. Nos. 4,189,323 and 8,431,325. PAGs that are onium salts typically can include an anion having a sulfonate group or a non-sulfonate type group, such as a sulfonamidate group, a sulfonimidate group, a methide group, or a borate group.

In an embodiment, an overcoat composition may optionally include a plurality of PAGs. The plural PAGs can be polymeric, non-polymeric, or can include both polymeric and non-polymeric PAGs. In some embodiments, each of the plurality of PAGs can be non-polymeric. In some embodiments, when a plurality of PAGs are used, a first PAG can include a sulfonate group on the anion and a second PAG can include an anion that is free of sulfonate groups, such anion containing for example, a sulfonamidate group, a sulfonimidate group, a methide group, or a borate group, such as described above, for example.

In some embodiments, the PAG can be a polymeric PAG, wherein the compound capable of generating an acid upon irradiation with actinic rays or radiation is introduced into the main or side chain of the polymer. For an SSA of an embodiment, examples can include, for example, compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853, and JP-A-63-146029.

In some embodiments, an overcoat composition can include a non-polymerized photoacid generator in an amount from about 1 to 65 wt %, from about 5 to 55 wt %, or from about 8 to 30 wt %, based on total solids of the photoresist composition, for example. In some embodiments, an overcoat composition can include two or more different non-polymerized photoacid generators in a combined amount from about 1 to 65 wt %, from about 5 to 55 wt %, or from about 8 to 30 wt %, based on total solids of the photoresist composition, for example. In some embodiments, a photoacid generator mixture can include two or three photoacid generators. Such mixtures can be of a same class or different classes. Examples of some preferred mixtures can include sulfonium salts with bis-sulfonyldiazomethane compounds, sulfonium salts and imidosulfonates, and two sulfonium salts, for example.

### Solubility Shifting Agent as Base or Base Generator

For an embodiment, suitable quencher base or base generators can include, but are not limited to, hydroxides, carboxylates, amines, imines, amides, or mixtures thereof. Specific examples of bases can include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, or combinations thereof. Amines can include aliphatic amines, cycloaliphatic amines, aromatic amines, or heterocyclic amines. The amine can be a primary, secondary, or tertiary amine. The amine can be a monoamine, diamine, or polyamine. Suitable amines can include C1-30 organic amines, imines, or amides, or may be a C1-30 quaternary ammonium salt of a strong base (e.g., a hydroxide or alkoxide) or a weak base (e.g., a carboxylate). In some embodiments, example bases can include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl) propane, Troger's base, a hindered amine such as diazabicycloundecene (DBU) or diazabicyclononene (DBN), amides like tert-butyl 1,3-dihydroxy-2-(hydroxymethyl) propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate.

In some embodiments, the amine can be a hydroxyamine. Examples of hydroxyamines can include hydroxyamines having one or more hydroxyalkyl groups each having 1 to about 8 carbon atoms, and sometimes preferably 1 to about 5 carbon atoms such as hydroxymethyl, hydroxyethyl and hydroxybutyl groups. Specific examples of hydroxy amines can include mono-, di- and tri-ethanolamine, 3-amino-1-propanol, 2-amino-2-methyl-1-propanol, 2-amino-2-ethyl-1,3-propanediol, tris(hydroxymethyl) aminomethane, N-methylethanolamine, 2-diethylamino-2-methyl-1-propanol, and triethanolamine.

In an embodiment, suitable base generators can be thermal base generators. A thermal base generator (TAG) can form a base upon heating above a first temperature, typically about 140° C. or higher. The thermal base generator can include a functional group such as an amide, sulfonamide, imide, imine, O-acyl oxime, benzoyloxycarbonyl derivative, quarternary ammonium salt, nifedipine, carbamate, or combinations thereof, for example.

In an embodiment, example thermal base generators can include: o-{(.beta.-(dimethylamino)ethyl)aminocarbonyl}benzoic acid, o-{(.gamma.-(dimethylamino) propyl)aminocarbonyl}benzoic acid, 2,5-bis {(.beta.-(dimethylamino)ethyl)aminocarbonyl}terephthalic acid, 2,5-bis {(.gamma.-(dimethylamino) propyl)aminocarbonyl}terephthalic acid, 2,4-bis {(.beta.-(dimethylamino)ethyl) aminocarbonyl}isophthalic acid, 2,4-bis {(.gamma.-(dimethylamino) propyl)aminocarbonyl]isophthalic acid, or combinations thereof, for example.

### Optional Additives

In some embodiments, the relief pattern composition optionally includes other additives, wherein other additives include at least one of a resin having at least either a fluorine atom or a silicon atom, a basic compound, a surfactant, an onium carboxylate, dye, a plasticizer, a photosensitizer, a light absorbent, an alkali-soluble resin, a dissolution inhibitor, and a compound for accelerating dissolution in a developer.

### Overcoat Composition

In an embodiment of present disclosure, an overcoat composition of an overcoat (e.g., overcoats 130, 230 and 330 of FIGS. 1B, 2C, and 3C, respectively) can be a composition that can include a second polymer, a solvent, and may also contain additional, optional components, including a crosslinker.

### Second Polymer

In an embodiment, the second polymer can be a polymer made from monomers including acrylates, methacrylates, norbornene, vinyl aromatic monomers such as styrene and p-hydroxystyrene, combinations thereof, or the like. Each monomer can include a curable group, a linker group, a cleavable group, and/or a polymerizable group.

Exemplary structures of monomers can include, without limitation, the following:

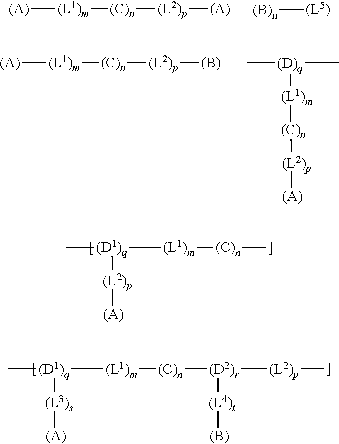

where A and B are curable groups, L¹-L⁵ are linker groups, C are cleavable groups, and D¹ and D² are polymerizable groups.

Example cleavable groups can include, without limitation, the following:

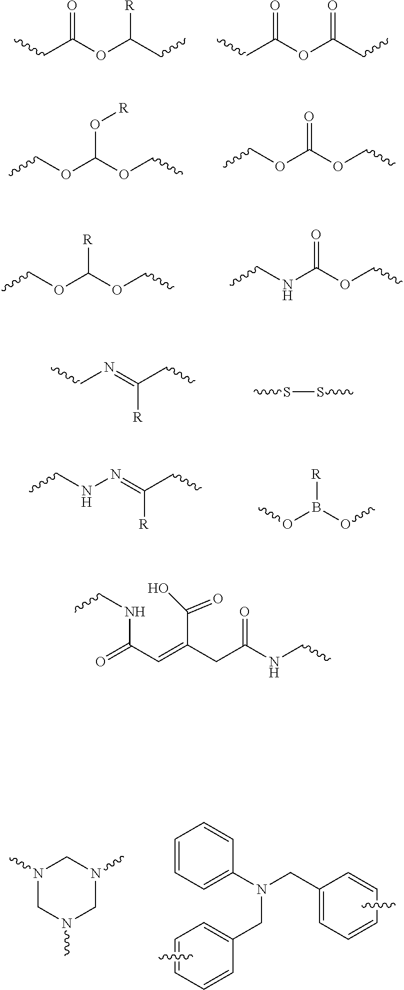

Crosslinking of monomers can be achieved by a variety of chemistries including the following non-limiting examples: vinyl ether+alcohol/carboxylic acid, glycouril+alcohol/carboxylic acid, benzocyclobutenes, oxiranes (epoxides), azides, azides+alkene/alkyne, acryloyl+free radical initiator, thiol+alkene, diazirines, diazo decomposition followed by carbene C—H insertion, or the like.

Example cross-linking chemistries can further include, without limitation, the following:

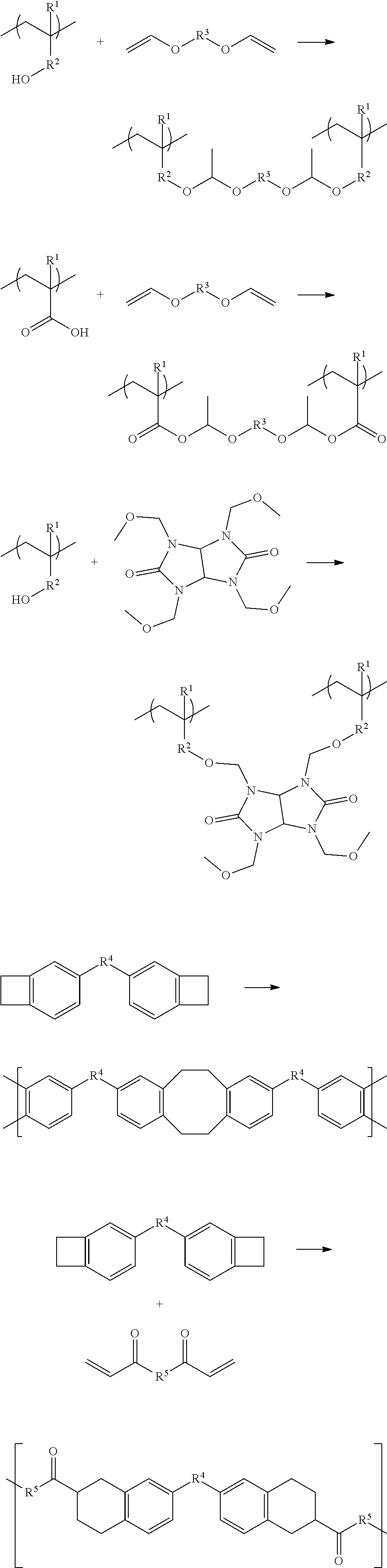

Example cleavable polyacrylate acrylates can include, without limitation, the following:

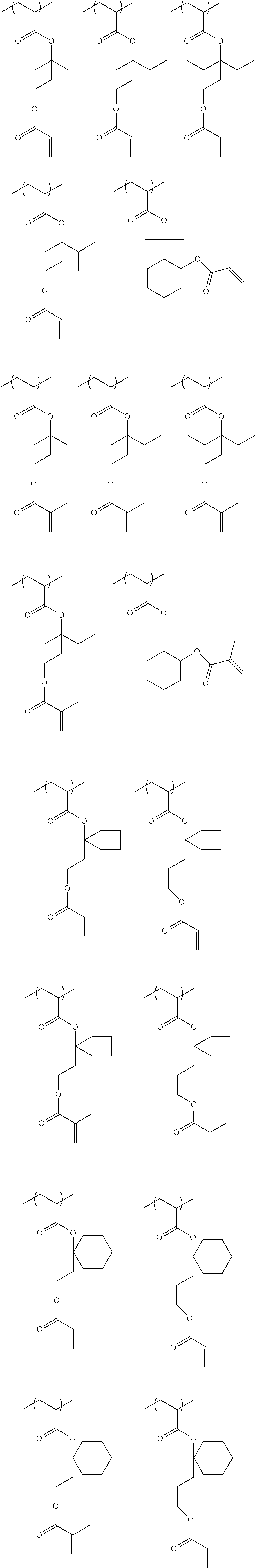

Example cleavable polyacrylate alcohols can include, without limitation, the following:

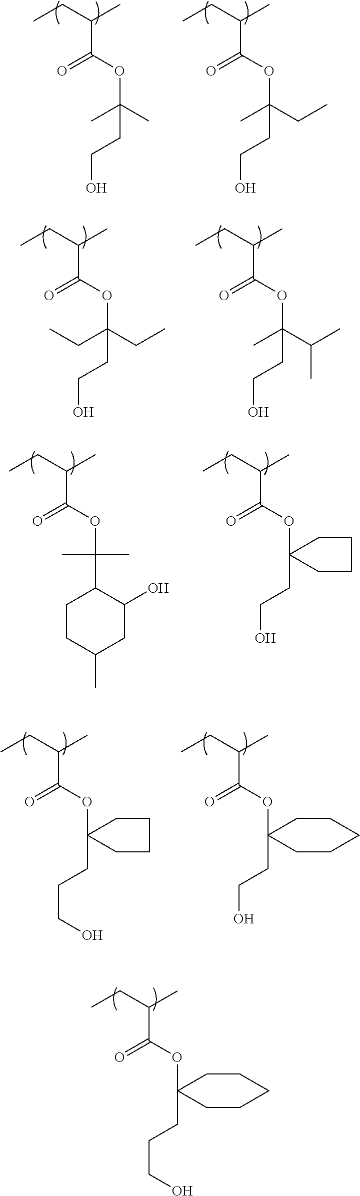

Example cleavable polyacrylate phthalates can include, without limitation, the following:

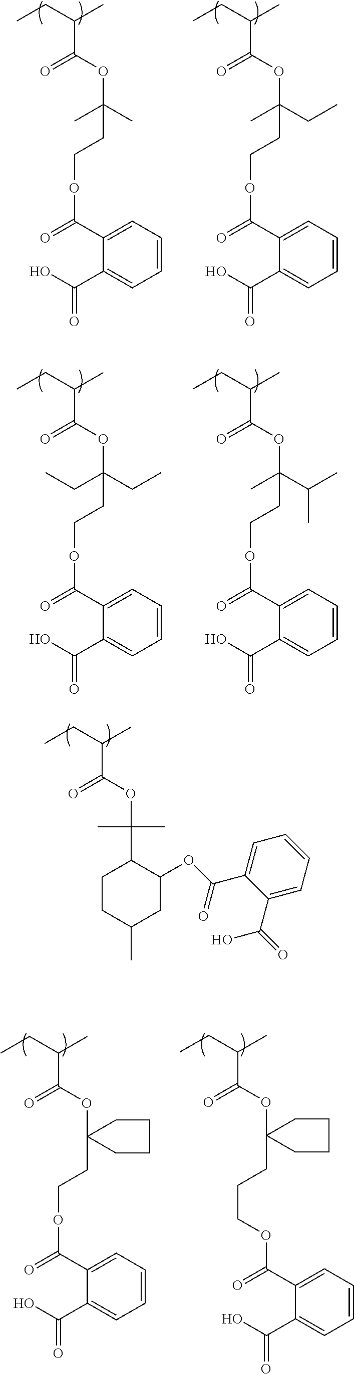

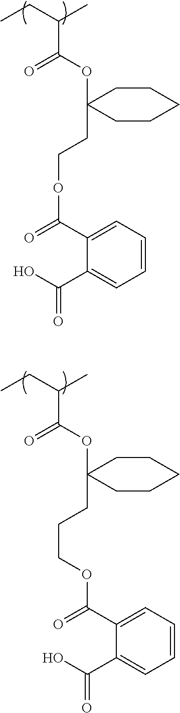

Example cleavable polymethacrylate acrylates can include, without limitation, the following:

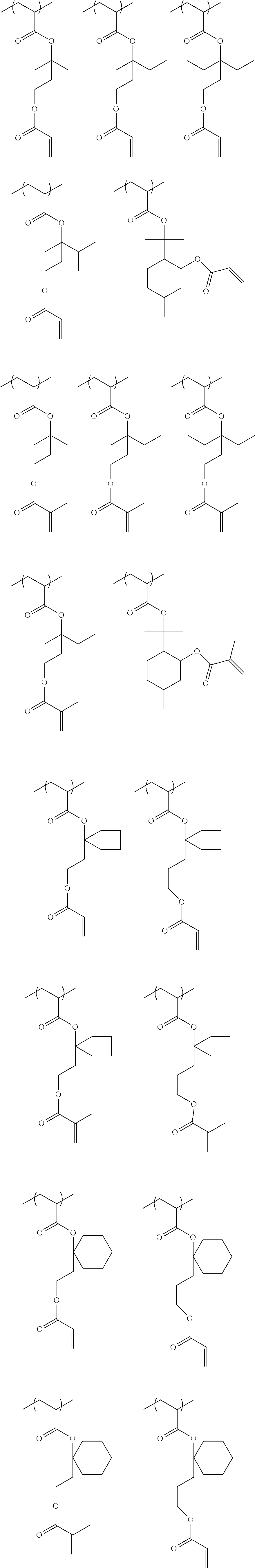

Example cleavable polymethacrylate alcohols can include, without limitation, the following:

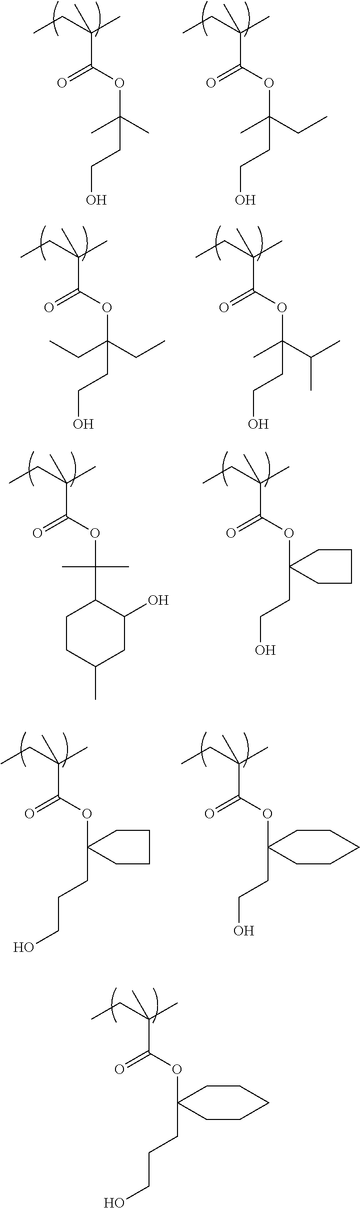

Example cleavable polystyrene alcohols can include, without limitation, the following:

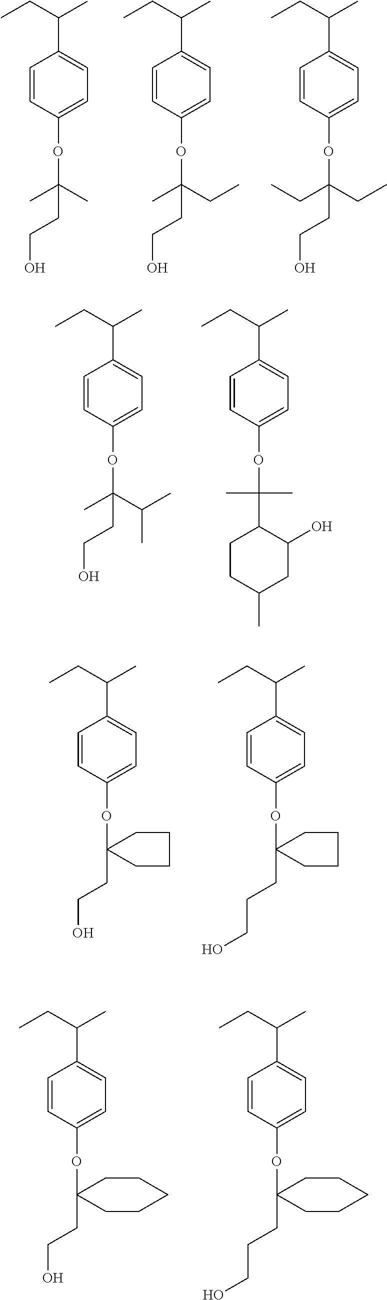

Example cleavable polystyrene phthalates can include, without limitation, the following:

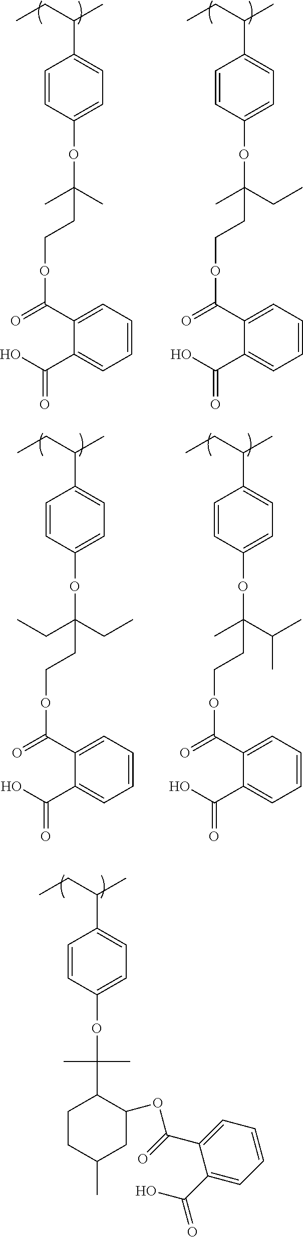

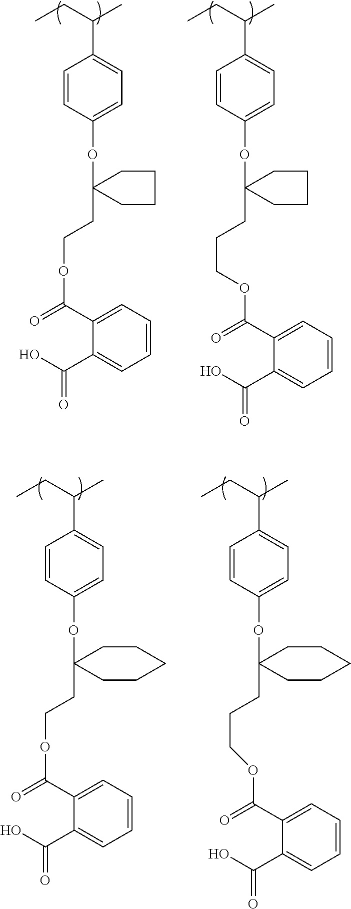

### Solvents

In an embodiment of the present disclosure, the overcoat composition of an overcoat (e.g., overcoats 130, 230 and 330 of FIGS. 1B, 2C, and 3C, respectively) comprises an organic solvent that can include an organic solvent conventionally used in the manufacture of electronic devices. When structures 122 are formed from a vinyl aromatic-based polymer, as is typical for KrF and EUV photoresists, and the resist can be developed as a PTD resist, the solvent and developer can contain a solvent system including one or more nonpolar organic solvents. The term “nonpolar organic-based” can indicate that the solvent system includes greater than 50 wt % of combined nonpolar organic solvents based on total solvents of the composition, more typically greater than 70 wt %, greater than 85 wt % or 100 wt %, combined nonpolar organic solvents, based on total solvents of the composition. The nonpolar organic solvents can be typically present in the solvent system in a combined amount of from 70 to 98 wt %, preferably 80 to 95 wt %, more preferably from 85 to 98 wt %, based on the solvent system, for example.

In an embodiment, suitable nonpolar solvents can include, for example, ethers, hydrocarbons, and combinations thereof, with ethers being sometimes preferred. In an embodiment, suitable ether solvents can include, for example, alkyl monoethers and aromatic monoethers, particularly preferred of which can be those having a total carbon number of from 6 to 16. In an embodiment, suitable alkyl monoethers can include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. In an embodiment, suitable aromatic monoethers can include, for example, anisole, ethylbenzyl ether, diphenyl ether, dibenzyl ether and phenetole, with anisole being preferred. In an embodiment, suitable aliphatic hydrocarbons can include, for example, n-heptane, 2-methylheptane, 3-methylheptane, 3, 3-dimethylhexane, 2,3,4-trimethylpentane, n-octane, n-nonane, n-decane, and fluorinated compounds such as perfluoroheptane. In an embodiment, suitable aromatic hydrocarbons can include, for example, benzene, toluene, and xylene.

In some embodiments, the solvent system can further include one or more alcohol and/or ester solvents. For certain compositions, an alcohol and/or ester solvent can provide enhanced solubility with respect to the solid components of the composition. In an embodiment, suitable alcohol solvents can include, for example: straight, branched or cyclic C4-9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C5-9 fluorinated diols such as 2,2,3,3,4,4-hexafluoro-1,5-pentanediol, 2,2,3,3,4,4,5,5-octafluoro-1,6-hexanediol, or 2,2,3,3,4,4,5,5,6,6,7,7-dodecafluoro-1,8-octanediol. In an embodiment, an alcohol solvent can be preferably a C4-9 monohydric alcohol, with 4-methyl-2-pentanol being preferred. In an embodiment, suitable ester solvents can include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in a solvent system for a developer of an embodiment, can be typically present in a combined amount of from 2 to 50 wt %, more typically in an amount of from 2 to 30 wt %, based on the solvent system, for example.

In an embodiment, a solvent system can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, can be typically present in a combined amount of from 1 to 20 wt % based on the solvent system.

In an embodiment, when the structures 122 (see FIG. 1A) are formed from a vinyl aromatic-based polymer, a preferred organic-based solvent system can include one or more monoether solvents in a combined amount of from 70 to 98 wt % based on the solvent system, and one or more alcohol and/or ester solvents in a combined amount of from 2 to 30 wt % based on the solvent system. The solvent system can be typically present in an amount of from 90 to 99 wt %, preferably from 95 to 99 wt %, based on the composition, for example. In an embodiment in which structures 122 are formed from an NTD resist, a suitable organic solvent can include, but is not limit to, n-butyl acetate, 2-heptanone, propylene glycol methyl ether, propylene glycol methyl ether acetate, and combinations thereof, for example.

### Crosslinkers

In an embodiment of present disclosure, an overcoat composition of an overcoat (e.g., overcoats 130, 230 and 330 of FIGS. 1B, 2C, and 3C, respectively) can optionally contain a crosslinker component. Preferred compositions of the present disclosure can be crosslinked, e.g. by thermal and/or radiation treatment. The crosslinker component is generally a compound capable of reacting with the one or more functional groups capable of crosslinking. Examples, without limitation, of such crosslinking agents are resins containing melamines, methylols, glycoluril, polymeric glycolurils, benzoguanamine, urea, hydroxy alkyl amides, epoxy and epoxy amine resins, blocked isocyanates, and divinyl monomers. For example, suitable crosslinkers include amine-based crosslinkers such as a melamine materials, including melamine resins such as manufactured by American Cyanamid and sold under the tradename of Cymel 300, 301, 303, 350, 370, 380, 1116 and 1130. Glycourils are particularly preferred including glycourils available from American Cyanamid. Benzoquanamines and urea-based materials also will be suitable including resins such as the benzoquanamine resins available from American Cyanamid under the name Cymel 1123 and 1125, and urea resins available from American Cyanamid under the names of Beetle 60, 65 and 80. Aromatic methylols, like 2,6 bishydroxymethyl p-cresol, can also be used. In addition to being commercially available, such amine-based resins may be prepared e.g. by the reaction of acrylamide or methacrylamide copolymers with formaldehyde in an alcohol-containing solution, or alternatively by the copolymerization of N-alkoxymethyl acrylamide or methacrylamide with other suitable monomers.

Preferred crosslinkers include methoxy-methylated glycoluril, butoxy-methylated glycoluril, methoxy-methylated melamine, butoxy-methylated melamine, methoxymethyl benzoguanamine, butoxymethyl benzoguanamine, methoxymethyl urea, butoxymethyl urea, methoxymethyl thiourea or butoxymethyl thiourea, or a combination thereof. In addition, condensates of these compounds can also be used. Other suitable low basicity crosslinkers include hydroxy compounds, particularly polyfunctional compounds such as phenyl or other aromatics having one or more hydroxy or hydroxy alkyl substituents such as a C1-8 hydroxyalkyl substituents. Phenol compounds are generally preferred such as di-methanolphenol (C6H3 (CH2OH) 2OH) and other compounds having adjacent (within 1-2 ring atoms) hydroxy and hydroxyalkyl substitution, particularly phenyl or other aromatic compounds having one or more methanol or other hydroxylalkyl ring substituent and at least one hydroxy adjacent such hydroxyalkyl substituent. Preferred examples include substituted bi-phenol compounds, substituted tris-phenol compounds, methylolated phenol compounds, methylolated bisphenol compounds, substituted phenol novolaks, substituted cresol novolaks,

Additional groups capable of reacting with the resin include for example epoxy group, oxetanyl group, oxazoline group, cyclocarbonate group, alkoxysilyl group, alkoxyalkyl group, aziridinyl group, methylol group, hydroxy group, isocyanate group, acetal group, hydroxysilyl group, ketal group, vinylether group, aminomethylol group, alkoxymethylamino group and imino group, etc.

Such compounds include for example compounds having an epoxy group such as triglycidyl-p-aminophenol, tetraglycidyl meta-xylene diamine, tetraglycidyl diamino diphenylmethane, tetraglycidyl-1,3-bisaminomethylcyclohexane, bisphenol-A-diglycidyl ether, bisphenol-S-diglycidyl ether, resorcinol diglycidyl ether, diglycidyl phthalate, neopentyl glycol diglycidyl ether, polypropylene glycol diglycidyl ether, cresol novolak polyglycidyl ether, tetrabromo bisphenol-A-diglycidyl ether, bisphenol hexafluoro acetone diglycidyl ether, glycerin triglycidyl ether, pentaerythritol diglycidyl ether, tris-(2,3-epoxypropyl) isocyanurate, monoallyldiglycidyl isocyanurate, and glycidyl methacrylate, etc.

In addition, the polymer compound having a cyclocarbonate group includes for example a compound having a cyclocarbonate group obtained by the reaction of the compound having epoxy group with carbon dioxide, 1,2-propylene carbonate, phenyldioxolone, vinylethylene carbonate, butylene carbonate, tetrachloroethylene carbonate, chloroethylene glycol carbonate, 4-chloromethyl-1,3-dioxolan-2-one, 1,2-dichloroethylene carbonate, 4-(1-propenyloxymethyl)-1,3-dioxolan-2-one, glycerin carbonate, (chloromethyl)ethylene carbonate, 1-benzylglycelol-2,3-carbonate, 4,4-dimethyl-5-methylene-1,3-dioxolan-2-one, and 3,3,3-trifluoropropylene carbonate, etc.

The compound having an isocyanate group includes for example p-phenylenediisocyanate, biphenyldiisocyanate, methylenebis(phenylisocyanate), 2-isocyanate ethyl methacrylate, 1,4-cyclohexyl diisocyanate, 1,3,5-tris(6-isocyanatehexyl)triazinetrione, 1-isocyanatenaphthalene, 1,5-naphthalene diisocyanate, 1-butylisocyanate, cyclohexylisocyanate, benzylisocyanate, 4-chlorophenylisocyanate, isocyanate trimethylsilane, and hexylisocyanate, etc.

The compound having an alkoxysilyl group includes for example triethoxyoctylsilane, tris[3-trimethoxysilyl) propyl]isocyanurate, 3-trimethoxysilyl)-N-[3 (trimethoxysilyl) propyl]-1-propanamine, 3-(trimethoxysilyl) propylmethacrylate, 3-isocyanate propyltriethoxysilane, 1,4-bis(trimethoxysilyl)benzene, phenyltriethoxysilane, methyltriethoxysilane, (3-trimethoxysilylpropyl) maleate, 3-(2-aminoethylamino) propyltrimethoxysilane, methyltriactoxyslane, trimethoxy-2-(3,4-epoxycyclohexyl)ethylsilane, 3-trimethoxypropylsilane, 4-trimethoxysilylpropylmethacrylate, (chloromethyl)phenyltrimethoxysilane, 2-(3,4-epoxycyclohexyl)ethyltriethoxysilane, triethoxy-n-dodecylsilane and 2-mercaptoethyl triethoxysilane and the like.

Additional compounds include melamine compounds, urea compounds, glycoluril compounds and benzoguanamine compounds that the hydrogen atom of the amino group is substituted by methylol group or alkoxymethyl group. The concrete examples are hexamethoxymethyl melamine, tetramethoxymethyl benzoguanamine, 1,3,4,6-tetrakis(butoxymethyl) glycoluril, 1,3,4,6-tetrakis(hydroxymethyl) glycoluril, 1,3-bis(hydroxymethyl) urea, 1,1,3,3-tetrakis(butoxymethyl) urea, 1,1,3,3-tetrakis(methoxymethyl) urea, 1,3-bis(hydroxymethyl)-4,5-dihydroxy-2-imidazolinone, and 1,3-bis(methoxymethyl)-4,5-dimethoxy-2-imidazolinone, etc., and methoxymethyl type melamine compounds manufactured by Mitsui Cytec Co., Ltd. (trade name: Cymel 300, Cymel 301, Cymel 303, Cymel 350), butoxymethyl type melamine compounds (trade name: Mycoat 506, Mycoat 508), glycoluril compounds (trade name: Cymel 1170, Powderlink 1174), methylated urea resins (trade name: UFR 65), butylated urea resins (trade name: UFR300, U-VAN 10S60, U-VAN 10R, U-VAN 11HV), urea/formaldehyde resins manufactured by Dainippon Ink and Chemistry Incorporated (high condensation type, trade name: Beckamine J-300S, Beckamine P-955, Beckamine N) and the like. The compounds obtained by condensing the melamine compounds, urea compounds, glycoluril compounds and benzoguanamine compounds that the hydrogen atom of the amino group is substituted by methylol group or alkoxymethyl group, may be also used. For example, the compound includes a compound with a high molecular weight that is produced from a melamine compound (Cymel 303) and a benzoguanamine compound (trade name: Cymel 1123) that is disclosed in U.S. Pat. No. 6,323,310.

Additional preferred crosslinkers are vinyl ether crosslinkers. It is preferred that the vinyl ether crosslinkers be multi-functional, and more preferably tri- and tetra-functional.

Preferred vinyl ether crosslinkers have the formula:

R12—(J—O—CH═CH2)n

where R12 is selected from the group consisting of aryls (preferably C6-C12) and alkyls (preferably C1-C18, and more preferably C1-C10), each J is individually selected from the group consisting of: alkyls (preferably C1-C18, and more preferably C1-C10); alkoxys (preferably C1-C18, and more preferably C1-C10); carboxys; and combinations of two or more of the foregoing, and n is 2-6. The most preferred vinyl ether crosslinkers include those selected from the group consisting of ethylene glycol vinyl ether, trimethylolpropane trivinyl ether, 1,4-cyclohexane dimethanol divinyl ether, {2-[(2,4,5-Tris {[2-(vinyloxy) ethoxy]methyl}phenyl) methoxy]ethoxy}ethene, tri[2-(vinyloxy)ethyl]1,3,5-benzenetricarboxylate, and mixtures thereof.

It has been found that a low basicity crosslinker such as a methoxy methylated glycouril used in antireflective compositions of the present disclosure can provide excellent lithographic performance properties, including significant reduction of undercutting or footing of an overcoated photoresist relief image.

A crosslinker component of antireflective compositions of the present disclosure in general is present in an amount of between 5 and 50 weight percent of total solids (all components except solvent carrier) of the antireflective composition, more typically in an amount of about 7 to 25 weight percent total solids.

### Developers

In an embodiment of the present disclosure, a developer that contains an organic solvent can include an organic solvent conventionally used in the manufacture of electronic devices. In an embodiment of the present disclosure, a developer that contains an organic solvent can include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol and 4-methyl-2-pentanol; propylene glycol monomethyl ether (PGME), ethers such as diethyl ether, tetrahydrofuran, 1,4-dioxane and anisole; ketones such as acetone, methyl ethyl ketone, methyl iso-butyl ketone, 2-heptanone and cyclohexanone (CHO); esters such as ethyl acetate, n-butyl acetate, propylene glycol monomethyl ether acetate (PGMEA), ethyl lactate (EL), hydroxyisobutyrate methyl ester (HBM) and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; and combinations thereof, for example. Of these, some preferred organic solvents can be PGME, PGMEA, EL, GBL, HBM, CHO, or combinations thereof, for example.

The exposed resist layer may be developed with either a positive tone development (PTD) or negative tone development (NTD) process. In an embodiment, suitable developers for a PTD process can include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like, for example.

Conversely, in an embodiment, suitable developers for an NTD process can be organic solvent-based, which can mean the cumulative content of organic solvents in the developer is 50 wt % or more, typically 95 wt % or more, 98 wt % or more, or 100 wt %, based on total weight of the developer. For an embodiment, suitable organic solvents for the PTD developer can include, for example, those chosen from ketones, esters, ethers, hydrocarbons, and mixtures thereof. In an embodiment, a developer can be typically 2-heptanone or n-butyl acetate.

Example embodiments of the disclosure are described below. Other embodiments can also be understood from the entirety of the specification as well as the claims filed herein.

Example 1. A method including depositing an overcoat in openings of a relief pattern supported by a substrate. The relief pattern includes a solubility-shifting agent. The overcoat and the relief pattern have different solubility-shifting mechanisms. The method further including generating a catalyst by activating the solubility-shifting agent and diffusing the catalyst a predetermined distance from structures of the relief pattern into the overcoat to form soluble regions in the overcoat. The soluble regions is soluble in a predetermined developer while the relief pattern remains insoluble in the predetermined developer. The method further including developing the substrate with the predetermined developer to remove the soluble regions of the overcoat.

Example 2. The method of example 1, where the solubility-shifting agent is a thermal acid generator, and where activating the solubility-shifting agent includes applying heat to the substrate to activate the solubility-shifting agent.

Example 3. The method of example 2, further including forming the relief pattern on the substrate, the relief pattern further comprising a photoacid generator different from the solubility-shifting agent, where forming the relief pattern includes forming the relief pattern from a layer of photoresist by exposing the layer of photoresist to actinic radiation to activate the photoacid generator.

Example 4. The method of example 2, further including forming the relief pattern on the substrate, the solubility-shifting agent also being a photoacid generator, where forming the relief pattern includes forming the relief pattern from a layer of photoresist by exposing the layer of photoresist to actinic radiation to activate the solubility-shifting agent.

Example 5. The method of one of examples 1 to 4, where the relief pattern further includes a polymer including acid-labile groups.

Example 6. The method of one of examples 1 to 5, where the overcoat includes a polymer including curable groups and cleavable groups.

Example 7. The method of one of examples 1 to 6, wherein the overcoat includes a degradable thermoset.

Example 8. The method of one of examples 1 to 7, where the overcoat includes polyacrylate phthalates, polystyrene phthalates, polystyrene alcohols, polymethacrylate alcohols, polyacrylate alcohols, polymethacrylate acrylates, or polyacrylate acrylates.

Example 9. The method of one of examples 1 to 8, where the predetermined developer includes an organic developer.

Example 10. A method including providing a substrate with a relief pattern thereon. The relief pattern includes a solubility-shifting agent. The relief pattern includes a first material including acid-labile groups. The method further including depositing an overcoat over the relief pattern. The overcoat includes a second material including curable groups and cleavable groups. The method further including generating a catalyst from the solubility-shifting agent, diffusing the catalyst from the relief pattern into the overcoat to form deprotected regions in the overcoat, and selectively removing the deprotected regions of the overcoat.

Example 11. The method of example 10, further including, before generating the catalyst from the solubility-shifting agent, curing the overcoat.

Example 12. The method of one of examples 10 and 11, where the second material includes a degradable thermoset.

Example 13. The method of one of examples 10 to 12, wherein the second material includes polyacrylate phthalates, polystyrene phthalates, polystyrene alcohols, polymethacrylate alcohols, polyacrylate alcohols, polymethacrylate acrylates, or polyacrylate acrylates.

Example 14. The method of one of examples 10 to 13, where the diffused catalyst cleaves cleavable bonds of the cleavable groups of the second material.

Example 15. The method of one of examples 10 to 14, where the second material further includes linker groups and polymerizable groups.

Example 16. A method including forming a relief pattern on a substrate from a layer of photoresist by exposing the photoresist to actinic radiation to activate a photoacid generator. The photoresist includes the photoacid generator and a solubility-shifting agent. The method further including depositing an overcoat in openings of the relief pattern. The overcoat includes a degradable thermoset. The method further including curing the overcoat, generating a catalyst from the solubility-shifting agent, diffusing the catalyst from the relief pattern into the overcoat to form deprotected regions in the overcoat, and selectively removing the deprotected regions of the overcoat.

Example 17. The method of example 16, where the solubility-shifting agent is a thermal acid generator, and where generating the catalyst from the solubility-shifting agent includes applying heat to the substrate to activate the solubility-shifting agent.

Example 18. The method of one of examples 16 and 17, where the degradable thermoset includes curable groups and cleavable groups.

Example 19. The method of one of examples 16 to 18, where the diffused catalyst cleaves cleavable bonds of the cleavable groups.

Example 20. The method of one of examples 16 to 19, where the degradable thermoset further includes linker groups and polymerizable groups.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
depositing an overcoat in openings of a relief pattern supported by a substrate, the relief pattern comprising a solubility-shifting agent, wherein the overcoat and the relief pattern have different solubility-shifting mechanisms;
generating a catalyst by activating the solubility-shifting agent;
diffusing the catalyst a predetermined distance from structures of the relief pattern into the overcoat to form soluble regions in the overcoat, the soluble regions being soluble in a predetermined developer while the relief pattern remains insoluble in the predetermined developer; and
developing the substrate with the predetermined developer to remove the soluble regions of the overcoat.

2. The method of claim 1, wherein the solubility-shifting agent is a thermal acid generator, and wherein activating the solubility-shifting agent comprises applying heat to the substrate to activate the solubility-shifting agent.

3. The method of claim 2, further comprising:
forming the relief pattern on the substrate, the relief pattern further comprising a photoacid generator different from the solubility-shifting agent, wherein forming the relief pattern comprises forming the relief pattern from a layer of photoresist by exposing the layer of photoresist to actinic radiation to activate the photoacid generator.

4. The method of claim 2, further comprising:
forming the relief pattern on the substrate, the solubility-shifting agent also being a photoacid generator, wherein forming the relief pattern comprises forming the relief pattern from a layer of photoresist by exposing the layer of photoresist to actinic radiation to activate the solubility-shifting agent.

5. The method of claim 1, wherein the relief pattern further comprises a polymer comprising acid-labile groups.

6. The method of claim 1, wherein the overcoat comprises a polymer comprising curable groups and cleavable groups.

7. The method of claim 1, wherein the overcoat comprises a degradable thermoset.

8. The method of claim 1, wherein the overcoat comprises polyacrylate phthalates, polystyrene phthalates, polystyrene alcohols, polymethacrylate alcohols, polyacrylate alcohols, polymethacrylate acrylates, or polyacrylate acrylates.

9. The method of claim 1, wherein the predetermined developer comprises an organic developer.

10. A method comprising:
providing a substrate with a relief pattern thereon, the relief pattern comprising a solubility-shifting agent, wherein the relief pattern comprises a first material comprising acid-labile groups;
depositing an overcoat over the relief pattern, wherein the overcoat comprises a second material comprising curable groups and cleavable groups;
generating a catalyst from the solubility-shifting agent;
diffusing the catalyst from the relief pattern into the overcoat to form deprotected regions in the overcoat; and
selectively removing the deprotected regions of the overcoat.

11. The method of claim 10, further comprising, before generating the catalyst from the solubility-shifting agent, curing the overcoat.

12. The method of claim 10, wherein the second material comprises a degradable thermoset.

13. The method of claim 10, wherein the second material comprises polyacrylate phthalates, polystyrene phthalates, polystyrene alcohols, polymethacrylate alcohols, polyacrylate alcohols, polymethacrylate acrylates, or polyacrylate acrylates.

14. The method of claim 10, wherein the diffused catalyst cleaves cleavable bonds of the cleavable groups of the second material.

15. The method of claim 10, wherein the second material further comprises linker groups and polymerizable groups.

16. A method comprising:
forming a relief pattern on a substrate from a layer of photoresist by exposing the photoresist to actinic radiation to activate a photoacid generator, the photoresist comprising the photoacid generator and a solubility-shifting agent;
depositing an overcoat in openings of the relief pattern, wherein the overcoat comprises a degradable thermoset;
curing the overcoat;
generating a catalyst from the solubility-shifting agent;
diffusing the catalyst from the relief pattern into the overcoat to form deprotected regions in the overcoat; and
selectively removing the deprotected regions of the overcoat.

17. The method of claim 16, wherein the solubility-shifting agent is a thermal acid generator, and wherein generating the catalyst from the solubility-shifting agent comprises applying heat to the substrate to activate the solubility-shifting agent.

18. The method of claim 16, wherein the degradable thermoset comprises curable groups and cleavable groups.

19. The method of claim 18, wherein the diffused catalyst cleaves cleavable bonds of the cleavable groups.

20. The method of claim 16, wherein the degradable thermoset further comprises linker groups and polymerizable groups.
